(19) United States
(12) Patent Application Publication
(10) Pub. No.: US 2023/0367050 A1
(43) Pub. Date: Nov. 16, 2023

(54) NEAR-INFRARED CUT FILTER AND IMAGING DEVICE HAVING SAME

(71) Applicant: HOYA CORPORATION, Tokyo (JP)

(72) Inventors: Haruna IMAI, Tokyo (JP); Takeshi YAMAZAKI, Tokyo (JP)

(73) Assignee: HOYA CORPORATION, Tokyo (JP)

(21) Appl. No.: 18/220,909

(22) Filed: Jul. 12, 2023

Related U.S. Application Data
(63) Continuation of application No. PCT/JP2022/000761, filed on Jan. 12, 2022.

(30) Foreign Application Priority Data
Jan. 13, 2021 (JP) 2021-003836

(51) Int. Cl. G02B 5/22; G02B 5/20

(52) U.S. Cl. CPC G02B 5/223; G02B 5/208; G02B 5/226; G03B 17/565

(57) ABSTRACT

A near-infrared cut filter is provided which has extremely low incident angle dependence and excellent oblique incidence characteristics. The near-infrared cut filter comprises a transparent substrate having a thickness of 0.16 to 0.26 mm and an average transmittance in a wavelength range of 800 to 1100 nm of 1% or less, and a resin layer formed at least one main surface of the transparent substrate and configured to absorb light of a specific wavelength.

### CLAIM FOR PRIORITY

This application is a Continuation of PCT/JP2022/000761 filed Jan. 12, 2022, and claims the priority benefit of Japanese application 2021-003836 filed Jan. 13, 2021, the contents of which are expressly incorporated by reference herein in their entireties.

### TECHNICAL FIELD

The present specification generally relates to near-infrared cut filters and imaging devices having the same, and more specifically to near-infrared cut filters that are arranged in front of solid-state image sensors and are for use to correct the sensitivity of visual perception of the solid-state image sensors, and imaging devices having the same.

### BACKGROUND ART

In recent years, imaging devices equipped with built-in solid-state image sensors such as CCD and CMOS have been used in digital cameras, information portable terminals, and the like. Since the solid-state image sensor has spectral sensitivity ranging from a near-ultraviolet region to a near-infrared region, such an imaging device is equipped with a near-infrared cut filter that cuts a near-infrared portion of incident light, thereby correcting the spectral sensitivity to make it close to the sensitivity of human visual perception. Such a near-infrared cut filter is placed in an optical path to the solid-state image sensor. In order to reduce the overall size of the imaging device, a near-infrared cut filter configured to also serve as a cover glass of the imaging device has been put to practical use (for example, Patent Literature 1).

FIG. 29 is an example of a structure of a near-infrared cut filter described in Patent Literature 1 (conventional example). As illustrated in FIG. 29, the near-infrared cut filter described in Patent Literature 1 includes a transparent substrate 13, an absorption layer 11 formed on one of the main surfaces of the transparent substrate 13 and configured to absorb light in a near-infrared wavelength region and an ultraviolet wavelength region and a reflective layer 12 formed on the other main surface of the transparent substrate 13 and configured to control transmission and blocking of light in specific wavelength ranges. The reflective layer 12 is composed of a dielectric multilayer film with a thickness of 2 to 10 µm in which dielectric films having a low refractive index (low dielectric films) and dielectric films having a high refractive index (high dielectric films) are alternately stacked. The reflective layer 12 is configured to have a spectral transmittance that satisfies predetermined requirements, so that a near-infrared cut filter is achieved which has spectral characteristics close to the spectral luminous efficiency curve especially on a long wavelength side and which has low incident angle dependence.

### CITATION LIST

### Patent Literature

Patent Literature 1: Japanese Patent No. 6119920

### SUMMARY

### Technical Problem

However, the near-infrared cut filter described in Patent Literature 1 includes the reflective layer 12 composed of the relatively thick dielectric multilayer film (the thickness of 2 to 10 µm), and therefore has a problem that, when light is obliquely incident on the reflective layer 12, the optical path of the light is so long that a phase shift occurs.

FIG. 30 is a diagram presenting spectral transmittance curves of the reflective layer 12 of the near-infrared cut filter in FIG. 29, and presents a spectral transmittance curve at an incident angle of 0° (solid line) and a spectral transmittance curve at an incident angle of 30° (dashed line). FIG. 31 is a diagram presenting spectral transmittance curves of the near-infrared cut filter in FIG. 29, and presents a spectral transmittance curve at an incident angle of 0° (solid line) and a spectral transmittance curve at an incident angle of 30° (dashed line).

As presented in FIG. 30, when light at an incident angle of 30° is incident on the reflective layer 12, there are problems that, due to a phase shift, the spectral transmittance curve shifts to a short wavelength side (P1 portion in FIG. 30) and ripples occur in the spectral transmittance curve (P2 portion in FIG. 30). Then, when the spectral transmittance curve of the reflective layer 12 shifts in wavelength, the spectral transmittance curve of the near-infrared cut filter also shifts in wavelength (P3 portion in FIG. 31), and the color reproducibility of the solid-state image sensor may deteriorate. When the spectral transmittance curve of the reflective layer 12 ripples, the spectral transmittance curve of the near-infrared cut filter also ripples (P4 portion in FIG. 31), and a kind of ghost may be observed on the solid-state image sensor. For these reasons, there is a demand for a near-infrared cut filter having excellent oblique incidence characteristics that will not cause a wavelength shift or ripples even with obliquely-incident light.

The present invention was made in view of the above circumstances. Some embodiments provide a near-infrared cut filter having extremely low incident angle dependence and excellent oblique incidence characteristics, and an imaging device having such a near-infrared cut filter.

### Solution to Problem

The inventors made earnest study to achieve the above object by focusing on a wavelength range of 800 to 1100 nm in particular in the spectral transmittance curve of a transparent substrate made of a glass (such as, for example, a fluorophosphate-based glass or a phosphate-based glass) and found that use of a transparent substrate having a low average transmittance in the wavelength range of 800 to 1100 nm makes it possible to manufacture a cut filter that selectively transmits light in a visible light region without using a reflection film, which has been used in a near-infrared cut filter in the related art. The present invention was made based on the above findings.

Specifically, a near-infrared cut filter of one embodiment includes a transparent substrate having a thickness of 0.16 to 0.26 mm and an average transmittance in a wavelength range of 800 to 1100 nm of 1% or less, and a resin layer formed on at least one main surface of the transparent substrate and configured to absorb light of a specific wavelength.

With this structure, a reflective layer composed of a dielectric multilayer film as in the related art is unnecessary (in other words, the reflective layer is not included). For this reason, even when light is obliquely incident on the near-infrared cut filter, the optical path length hardly changes and occurrence of a phase shift is inhibited. Accordingly, a phase shift and ripples hardly occur in the spectral transmittance curve of the near-infrared cut filter.

In addition, a transmittance curve of the transparent substrate is preferably such that a half-value wavelength on a short wavelength side is 300 to 400 nm, and a half-value wavelength on a long wavelength side is 590 to 670 nm.

Moreover, the transparent substrate preferably has an average transmittance in a wavelength range of 650 to 720 nm of 40% or less.

Then, the transparent substrate preferably has an average transmittance in a wavelength range of 720 to 750 nm of 15% or less.

Further, the transparent substrate preferably has an average transmittance in a wavelength range of 800 to 1200 nm of 5% or less.

The resin layer may contain a transparent resin and a dye evenly dispersed in the transparent resin. In this case, the dye preferably contains an ultraviolet absorbing dye having a maximum absorption wavelength at 340 to 400 nm. Also, the dye preferably contains a near-infrared absorbing dye having a maximum absorption wavelength at 650 to 900 nm.

The resin layer contains Si atoms as an essential component, and may contain one or more kinds selected from Ti atoms, Zr atoms, and Al atoms as an optional component.

A bonding layer for enhancing the adhesion between the transparent substrate and the resin layer may be provided between the transparent substrate and the resin layer. In this case, it is preferable to further provide the bonding layer on the other main surface of the transparent substrate. The bonding layer preferably has a single-layer structure containing one or more kinds selected from Ti atoms, Zr atoms, and A1 atoms together with Si atoms. In this case, in the bonding layer, it is preferable that a percentage of the total number of Ti atoms, Zr atoms, and Al atoms to the total number of Si atoms, Ti atoms, Zr atoms, and Al atoms be more than 0 atomic% and be equal to or less than 50 atomic%.

Also, the near-infrared cut filter may include a first functional film on the resin layer, and a second functional film on the other main surface of the transparent substrate. In this case, the first functional film and the second functional film are preferably optical thin films each having at least one or more of functions of an anti-reflective film, an infrared cut film, and an ultraviolet cut film. In this case, each of the first functional film and the second functional film is preferably composed of a dielectric multilayer film having a thickness of 500 nm or less. In this case, the dielectric multilayer film preferably has 10 or less layers.

The dielectric multilayer film is preferably formed by alternately stacking low refractive index dielectric films made of a material having a refractive index of 1.1 to 1.5 and high refractive index dielectric films made of a material having a refractive index of 2.0 to 2.5.

Instead, the dielectric multilayer film is preferably formed by alternately stacking low refractive index dielectric films made of a material having a refractive index of 1.1 to 1.3 and high refractive index dielectric films made of a material having a refractive index of 1.4 to 1.6.

In addition, a transmittance curve is preferably such that a half-value wavelength on a short wavelength side is 385 to 430 nm, and a half-value wavelength on a long wavelength side is 590 to 660 nm.

A difference between the half-value wavelength on the long wavelength side in the transmittance curve of the transparent substrate and the half-value wavelength on the long wavelength side in the transmittance curve of the near-infrared cut filter is preferably 20 nm or less.

The transparent substrate is preferably made of a fluorophosphate-based glass or a phosphorus-based glass.

In another aspect, an imaging device of another embodiment includes a solid-state image sensor and any of the above near-infrared cut filters. In this case, the near-infrared cut filter may be arranged immediately in front of the solid-state image sensor and configured to also serve as a cover glass.

According to some embodiments, a near-infrared cut filter having extremely low incident angle dependence and excellent oblique incidence characteristics as described above is achieved. In addition, an imaging device including such a near-infrared cut filter and having excellent color reproducibility is achieved.

### BRIEF DESCRIPTION OF DRAWINGS

FIGS. 1A and 1B include views for explaining a structure of a near-infrared cut filter according to a first embodiment of the present invention.

FIG. 2 is a vertical cross-sectional view for explaining a structure of an imaging device equipped with the near-infrared cut filter according to the first embodiment of the present invention.

FIG. 3 is a diagram presenting spectral transmittance curves of a near-infrared cut filter and a glass substrate used in the near-infrared cut filter according to the first embodiment of the present invention (Example 1).

FIG. 4 is a diagram presenting spectral transmittance curves of a near-infrared cut filter and a glass substrate used in the near-infrared cut filter according to the first embodiment of the present invention (Example 2).

FIG. 5 is a diagram presenting spectral transmittance curves of a near-infrared cut filter and a glass substrate used in the near-infrared cut filter according to the first embodiment of the present invention (Example 3).

FIG. 6 is a diagram presenting spectral transmittance curves of a near-infrared cut filter and a glass substrate used in the near-infrared cut filter according to the first embodiment of the present invention (Example 4).

FIG. 7 is a diagram presenting spectral transmittance curves of a near-infrared cut filter and a glass substrate used in the near-infrared cut filter according to the first embodiment of the present invention (Example 5).

FIG. 8 is a diagram presenting spectral transmittance curves of a near-infrared cut filter and a glass substrate used in the near-infrared cut filter according to the first embodiment of the present invention (Example 6).

FIG. 9 is a diagram presenting spectral transmittance curves of a near-infrared cut filter and a glass substrate used in the near-infrared cut filter according to the first embodiment of the present invention (Example 7).

FIG. 10 is a diagram presenting spectral transmittance curves of a near-infrared cut filter and a glass substrate used in the near-infrared cut filter according to the first embodiment of the present invention (Example 8).

FIG. 11 is a diagram presenting spectral transmittance curves of a near-infrared cut filter and a glass substrate used in the near-infrared cut filter according to the first embodiment of the present invention (Example 9).

FIG. 12 is a diagram presenting spectral transmittance curves of a near-infrared cut filter and a glass substrate used in the near-infrared cut filter according to the first embodiment of the present invention (Example 10).

FIG. 13 is a diagram presenting spectral transmittance curves of a near-infrared cut filter and a glass substrate used in the near-infrared cut filter according to the first embodiment of the present invention (Example 11).

FIG. 14 is a vertical cross-sectional view for explaining a structure of a near-infrared cut filter according to a second embodiment of the present invention.

FIG. 15 is a diagram presenting spectral transmittance curves of a near-infrared cut filter according to the second embodiment of the present invention (Example 12).

FIG. 16 is a diagram presenting spectral transmittance curves of a near-infrared cut filter according to the second embodiment of the present invention (Example 13).

FIG. 17 is a diagram presenting spectral transmittance curves of a near-infrared cut filter according to the second embodiment of the present invention (Example 14).

FIG. 18 is a diagram presenting spectral transmittance curves of a near-infrared cut filter according to the second embodiment of the present invention (Example 15).

FIG. 19 is a diagram presenting spectral transmittance curves of a near-infrared cut filter according to the second embodiment of the present invention (Example 16).

FIG. 20 is a diagram presenting spectral transmittance curves of a near-infrared cut filter according to the second embodiment of the present invention (Example 17).

FIG. 21 is a diagram presenting spectral transmittance curves of a near-infrared cut filter according to the second embodiment of the present invention (Example 18).

FIG. 22 is a diagram presenting spectral transmittance curves of a near-infrared cut filter according to the second embodiment of the present invention (Example 19).

FIG. 23 is a diagram presenting spectral transmittance curves of a near-infrared cut filter according to the second embodiment of the present invention (Example 20).

FIG. 24 is a diagram presenting spectral transmittance curves of a near-infrared cut filter according to the second embodiment of the present invention (Example 21).

FIG. 25 is a diagram presenting spectral transmittance curves of a near-infrared cut filter according to the second embodiment of the present invention (Example 22).

FIG. 26 is a vertical cross-sectional view for explaining a structure of a near-infrared cut filter according to a third embodiment of the present invention (Example 23).

FIG. 27 is a vertical cross-sectional view for explaining a structure of a near-infrared cut filter according to the third embodiment of the present invention (Example 24).

FIG. 28 is a vertical cross-sectional view for explaining a structure of a near-infrared cut filter according to the third embodiment of the present invention (Example 25).

FIG. 29 is a vertical cross-sectional view illustrating a structure of a near-infrared cut filter in the related art.

FIG. 30 is a diagram presenting spectral transmittance curves of a reflective layer used in the near-infrared cut filter in the related art.

FIG. 31 is a diagram presenting spectral transmittance curves of the near-infrared cut filter in the related art.

### DESCRIPTION OF EMBODIMENT

An embodiment of the present invention will be described below in detail with reference to the drawings. Here, the same or equivalent portions in the drawings are assigned with the same reference sign and their repetitive explanation will be omitted.

### First Embodiment

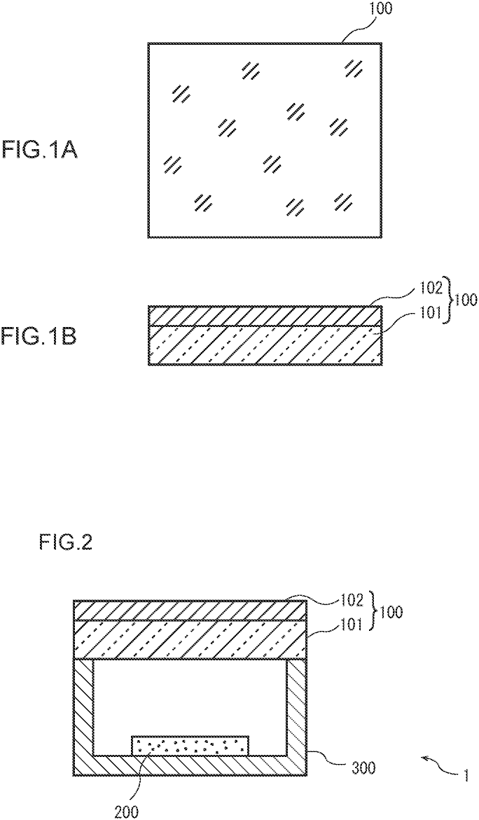

FIG. 1 includes views for explaining a structure of a near-infrared cut filter 100 according to a first embodiment of the present invention, in which FIG. 1A is a plan view and FIG. 1B is a cross-sectional view. FIG. 2 is a vertical cross-sectional view for explaining a structure of an imaging device 1 in which an opening portion of a package 300 for a solid-state image sensor 200 is sealed with the near-infrared cut filter 100 in the present embodiment. As illustrated in FIG. 1 and FIG. 2, the near-infrared cut filter 100 in the present embodiment is an optical element attached to a front surface of the package 300 in which the solid-state image sensor 200 is housed, and used to correct the sensitivity of visual perception of the solid-state image sensor 200 while protecting the solid-state image sensor 200.

As illustrated in FIG. 1, the near-infrared cut filter 100 in the present embodiment has an appearance of a rectangular plate (for example, 6 mm (horizontal direction) × 5 mm (vertical direction)) and includes a glass substrate 101 (transparent substrate) and a resin layer 102 formed on one main surface of the glass substrate 101 (an upper surface in FIG. 1B).

### [Glass Substrate]

The glass substrate 101 in the present embodiment is an absorbing glass substrate made of, for example, a phosphate-based glass or a fluorophosphate-based glass. From the viewpoint of size and weight reduction, The glass substrate 101 in the present embodiment has a thickness of preferably 0.35 mm or less and more preferably 0.16 to 0.26 mm.

The phosphate-based glass in the present embodiment is a glass containing P and O as essential components and another optional component, and is particularly preferably a glass containing CuO. When the phosphate-based glass contains CuO, the glass substrate can more effectively absorb near-infrared light. Examples of the other optional component of the phosphate-based glass include Ca, Mg, Sr, Ba, Li, Na, K, Cs, and so on.

A specific example of the phosphate-based glass preferably contains
P₂O₅: more than 0% by mass to 80% by mass or less,
Al₂O₃: 0 to 40% by mass,
BaO: 0 to 40% by mass, and
CuO: 0 to 40% by mass.

Meanwhile, the fluorophosphate-based glass in the present embodiment is a glass containing P, O, and F as essential components and another optional component, and is particularly preferably a glass containing CuO. When the fluorophosphate-based glass contains CuO, the glass substrate can more effectively absorb near-infrared light. Examples of the other optional component of the fluorophosphate-based glass include Ca, Mg, Sr, Ba, Li, Na, K, Cs, and so on.

As the fluorophosphate-based glass, a glass containing BaO is preferably used. When the glass contains BaO at 0% or more, the devitrification resistance and the meltability of the glass can be improved. Since the glass tends to be devitrified when containing BaO at more than 10%, the content of BaO is preferably 0 to 10%. The content of BaO is more preferably 1 to 10% and further preferably 1 to 5%.

As the fluorophosphate-based glass, a glass containing Al₂O₃ is preferably used. When the glass contains Al₂O₃ at 0% or more, the stability and the chemical durability of the glass can be improved. Since the glass tends to be devitrified when containing Al₂O₃ at more than 10%, the content of Al₂O₃ is preferably 0 to 10%. The content of Al₂O₃ is more preferably 1 to 10% and further preferably 1 to 5%.

As the fluorophosphate-based glass, a glass containing Y₂O₃ is preferably used. When the glass contains Y₂O₃ at 0% or more, the refractive index can be improved with the thermal stability maintained. Since the glass tends to be devitrified and has an increased glass transition temperature and an increased yield point temperature when containing Y₂O₃ at more than 10%, the content of Y₂O₃ is preferably 0 to 10%. The content of Y₂O₃ is more preferably 1 to 10% and further preferably 1 to 5%.

As the fluorophosphate-based glass, a glass containing BaCl₂ is preferably used. When BaCl₂ introduces an appropriate amount of Cl into the glass, a difference between the crystallization start temperature (Tx) and the glass transition temperature (Tg) of the glass increases to improve the anti-devitrification stability of the glass. Since the glass tends to be devitrified when containing BaCl₂ at more than 10%, the content of BaCl₂ is preferably 0 to 10%. The content of BaCl₂ is more preferably 1 to 10% and further preferably 1 to 5%.

A specific example of the fluorophosphate-based glass preferably contains:
P₂O₅: more than 0% by mass to 70% by mass or less,
Al₂O₃: 0 to 40% by mass,
BaO: 0 to 40% by mass, and
CuO: 0 to 40% by mass, and
further contains a fluoride at more than 0% by mass to 40% by mass or less.

A specific example of the fluorophosphate-based glass more preferably contains:
P₂O₅: 20 to 60% by mass,
Al₂O₃: 0 to 10% by mass,
BaO: 0 to 10% by mass, and
CuO: 0 to 10% by mass, and
further contains a fluoride at 1 to 30% by mass.

A specific example of the fluorophosphate-based glass further preferably contains:
P₂O₅: 20 to 60% by mass,
Al₂O₃: 1 to 10% by mass,
BaO: 1 to 10% by mass, and
CuO: 1 to 10% by mass, and
further contains a fluoride at 2 to 30% by mass.

The above fluoride is one or more kinds selected from MgF₂, CaF₂, SrF₂, and so on.

A specific example of the fluorophosphate-based glass particularly preferably contains:
P₂O₅: 40 to 50% by mass,
Al₂O₃: 1 to 10% by mass,
BaO: 1 to 10% by mass,
CuO: 1 to 10% by mass,
MgF₂: 1 to 10% by mass,
CaF₂: 1 to 10% by mass,
SrF₂: 1 to 10% by mass,
Y₂O₃: 1 to 10% by mass, and
BaCl₂: 0 to 1% by mass.

The glass substrate 101 in the present embodiment is configured such that an average transmittance in a wavelength range of 800 to 1100 nm is preferably 3% or less and more preferably 1% or less, as details will be described later. Use of the glass substrate 101 having the low average transmittance in the wavelength range of 800 to 1100 nm as described above makes it possible to manufacture a cut filter that selectively transmits light in a visible light region without using a reflection film (dielectric multilayer film), which has been used in a near-infrared cut filter in the related art.

In addition, the glass substrate 101 has an average transmittance in a wavelength range of 720 to 750 nm of preferably 15% or less, more preferably 10% or less, and further preferably 8% or less.

Then, the glass substrate 101 has an average transmittance in a wavelength range of 650 to 720 nm of preferably 40% or less, more preferably 10% or less, and further preferably 8% or less.

Further, the glass substrate 101 has an average transmittance in a wavelength range of 800 to 1200 nm of preferably 5% or less, more preferably 3% or less, and further preferably 2% or less.

The glass substrate 101 has a half-value wavelength on a short wavelength side (UV_λ50) in a transmittance curve preferably in a range of 300 to 400 nm, more preferably in a range of 305 to 350 nm, and further preferably in a range of 310 to 340 nm. The glass substrate 101 has a half-value wavelength on a long wavelength side (NIR_λ50) in the transmittance curve preferably in a range of 590 to 670 nm and more preferably in a range of 610 to 650 nm. In the present description, the half-value wavelength refers to a wavelength at which the transmittance is 50%, the half-value wavelength on the short wavelength side (UV_λ50) refers to a wavelength at which the transmittance reaches 50% at a rising edge of the transmittance curve, and the half-value wavelength on the long wavelength side (NIR_λ50) refers to a wavelength at which the transmittance reaches 50% at a falling edge of the transmittance curve.

### [Resin Layer]

The resin layer 102 in the present embodiment is a layer composed of a resin and a dye that absorbs light of a specific wavelength. The resin layer 102 contains a transparent resin and at least one of a near-infrared absorbing dye and an ultraviolet absorbing dye, and it is preferable that the dye be evenly dissolved or dispersed in the transparent resin, for example.

The resin layer 102 in the present embodiment preferably contains Si atoms as an essential component and contains one or more kinds selected from Ti atoms, Zr atoms, and Al atoms as an optional component.

As the near-infrared absorbing dye contained in the resin layer 102, conventionally known dyes may be employed. For example, one or more kinds selected from cyanine-based dyes, polymethine-based dyes, squarylium-based dyes, porphyrin-based dyes, metal dithiol complex-based dyes, phthalocyanine-based dyes, diimonium-based dyes, and inorganic oxide particles, or the like may be used, and one or more kinds selected from squarylium-based dyes, cyanine-based dyes, and phthalocyanine-based dyes are more preferable.

As the ultraviolet absorbing dye contained in the resin layer 102, conventionally known dyes may be employed. For example, one or more kinds selected from benzotriazole-based compounds, benzophenone-based compounds, triazine-based compounds, styryl-based compounds, benzoxazinone-based compounds, cyanoacrylate-based compounds, oxanilide-based compounds, salicylate-based compounds, formamidine-based compounds, indole-based compounds, and azomethine-based compounds, or the like may be used, and one or more kinds selected from benzotriazole-based compounds, benzophenone-based compounds, triazine-based compounds, and styryl-based compounds are more preferable.

As the resin contained in the resin layer 102, conventionally known transparent resins may be employed and one or more kinds selected from acrylic resins, epoxy resins, ene-thiol resins, polycarbonate resins, polyether resins, polyarylate resins, polysulfone resins, polyether sulfone resins, polyparaphenylene resins, polyarylene ether phosphine oxide resins, polyimide resins, polyamideimide resins, polyolefin resins, cyclic olefin resins, and polyester resins may be used. As the transparent resin, a resin having a high glass transition point (Tg) is preferable from the viewpoints of transparency, solubility of the near-infrared absorb dye in the transparent resin, and thermostability, and therefore a thermosetting resin is suitable. Specifically, one or more kinds selected from polyester resins, polycarbonate resin, polyether sulfone resins, polyarylate resins, polyimide resins, and epoxy resins may be used. As the polyester resins, one or more kinds selected from polyethylene terephthalate resins and polyethylene naphthalate resins are preferable. Even a thermoplastic resin may be suitably used as the transparent resin when the thermostability thereof is enhanced by adjustment of functional groups and the like. For example, as the transparent resin, an acrylic resin, a polyamide-based resin, a polyolefin-based resin, or the like whose thermostability can be enhanced by adjustment of functional groups and the like may be used.

In addition to the aforementioned near-infrared absorbing dye and transparent resin, the resin layer 102 may further contain optional components such as a color tone correcting dye, a leveling agent, an antistatic agent, a heat stabilizer, a light stabilizer, an antioxidant, a dispersant, a flame retardant, a lubricant, a plasticizer as long as the effects of the invention are not impaired.

For example, the resin layer 102 can be formed by preparing a resin film forming solution in which the dye, the transparent resin, and optional components are dissolved or dispersed in a solvent, applying and drying the resin film forming solution, and further, if necessary, curing the dried product. The resin film forming solution may contain a publicly known surfactant such as a cationic surfactant, an anionic surfactant, or a nonionic surfactant.

The resin film forming solution may be applied by using one or more kinds of coating methods selected from a dip coating method, a cast coating method, a spray coating method, a spin coating method, and the like.

As described above, the resin layer 102 is a layer formed on the glass substrate 101 and configured to absorb light of a specific wavelength, and is enabled to extract light in a desired visible light region with setting of an absorption wavelength depending on the spectral transmittance characteristics of the glass substrate 101 (in other words, with selection of an optimal dye).

Specifically, as the resin layer 102 in the present embodiment, a resin layer may be employed which contains an ultraviolet absorbing dye having a maximum absorption wavelength at 340 to 400 nm and a near-infrared absorbing dye having a maximum absorption wavelength at 650 to 900 nm.

Although the resin layer 102 in the present embodiment is formed on one main surface of the glass substrate 101 (the upper surface in FIG. 1B), embodiments are not limited to this structure. The resin layer 102 may be formed on the other main surface of the glass substrate 101 (the lower surface in FIG. 1B) or the resin layers 102 may be formed on both main surfaces of the glass substrate 101. Moreover, the resin layer 102 does not necessarily have to be a single layer, and may be composed of multiple layers.

Then, the spectral transmittance curve of the near-infrared cut filter 100 in which the aforementioned resin layer 102 is formed has characteristics close to the sensitivity of human visual perception (details will be described later) because the transmittance curve has a half-value wavelength on the short wavelength side (UV_λ50) of 385 to 430 nm, a half-value wavelength on the long wavelength side (NIR_λ50) of 590 to 660 nm, and an average transmittance in a wavelength range of 800 to 1100 nm of 3.0% or less.

Here, the near-infrared cut filter 100 in the present embodiment is attached in front of the front surface of the solid-state image sensor 200. For this reason, from the viewpoint of an amount of light incident on the solid-state image sensor 200, the near-infrared cut filter 100 preferably has a transmittance curve in which a difference between the half-value wavelength on the short wavelength side (UV_λ50) and the half-value wavelength on the long wavelength side (NIR_λ50) is large. In particular, the longer the half-value wavelength on the long wavelength side (NIR_λ50) within a range of the sensitivity of human visual perception, the better. Therefore, in the present embodiment, the half-value wavelength on the long wavelength side (NIR_λ50) in the transmittance curve of the near-infrared cut filter 100 is set to be close to the half-value wavelength on the long wavelength side (NIR_λ50) in the transmittance curve of the glass substrate 101. More specifically, in the present embodiment, the near-infrared cut filter 100 is configured such that the difference between the half-value wavelength on the long wavelength side (NIR_λ50) in the transmittance curve of the glass substrate 101 and the half-value wavelength on the long wavelength side (NIR_λ50) in the transmittance curve of the near-infrared cut filter 100 is 20 nm or less. The difference between the above two is more preferably 15 nm or less and further preferably 10 nm or less.

### [Imaging Device]

Next, an imaging device according to one embodiment will be described. As illustrated in FIG. 2, the imaging device 1 according to one embodiment includes a solid-state image sensor 200, a package 300 for housing the solid-state image sensor 200, and a near-infrared cut filter 100 attached to a front surface of the package 300.

The solid-state image sensor 200 is an image sensor such as a charge-coupled device (CCD) or a complementary metal oxide semiconductor (CMOS).

The solid-state image sensor 200 is placed on an approximately center portion of a bottom surface of the box-shaped package 300, and the near-infrared cut filter 100 is attached to the opening portion of the package 300 such that the other main surface of the near-infrared cut filter 100 (the lower side in FIG. 1B) faces the solid-state image sensor 200. In FIG. 2, the resin layer 102 side of the near-infrared cut filter 100 is an incident surface on which light traveling to the solid-state image sensor 200 is incident and the other main surface of the near-infrared cut filter 100 is an exit surface. However, the imaging device 1 is not limited to this structure. The near-infrared cut filter 100 may be attached upside down (in other words, such that the resin layer 102 faces the solid-state image sensor 200).

In the imaging device 1 in FIG. 2, the near-infrared cut filter 100 is attached to the opening portion of the package 300 and also serves as a so-called cover glass. However, the imaging device 1 is not limited to this structure. For example, the imaging device 1 may include a lens group (not illustrated) configured to guide light to the solid-state image sensor 200. In this case, for example, the near-infrared cut filter 100 may be placed closer to the imaging device 1 than the lens group is, and a cover glass may be provided closer to the imaging device 1 than the near-infrared cut filter 100 is.

Hereinafter, the near-infrared cut filter 100 in the present embodiment will be further described by using Examples and Comparative Examples, but the present invention should not be limited to Examples below.

### Example 1

### [1. Selection of Glass Substrate 101]

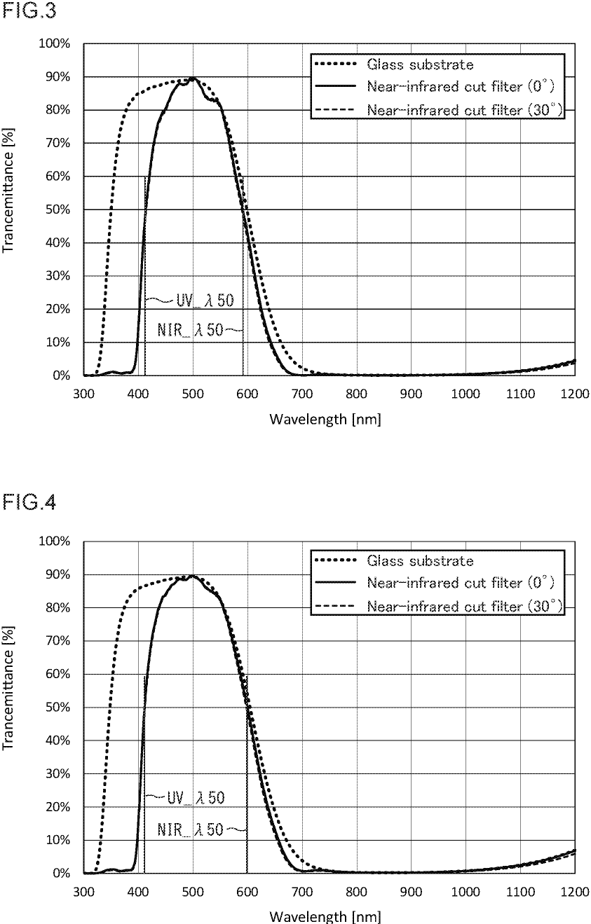

As the glass substrate 101 in Example 1, a fluorophosphate-based glass (CXD700, thickness 0.35 mm) manufactured by HOYA CORPORATION was selected. FIG. 3 is a diagram presenting a spectral transmittance curve (dotted line) of the glass substrate 101 in Example 1 and spectral transmittance curves (solid line and dashed line) of the near-infrared cut filter 100 in Example 1. In FIG. 3, the vertical axis is a transmittance (%), and the horizontal axis is a wavelength (nm). As the spectral transmittance curves of the near-infrared cut filter 100, FIG. 3 presents a spectral transmittance curve (solid line) at an incident angle of 0° and a spectral transmittance curve (dashed line) at an incident angle of 30°.

As presented in FIG. 3, the glass substrate 101 in Example 1 has an average transmittance in the wavelength range of 800 to 1100 nm of 0.34% (that is, 1% or less).

In addition, the glass substrate 101 in Example 1 has an average transmittance in the wavelength range of 720 to 750 nm of 0.62% (that is, 15% or less).

Moreover, the glass substrate 101 has an average transmittance in the wavelength range of 650 to 720 nm of 5.3% (that is, 40% or less).

Further, the glass substrate 101 has an average transmittance in the wavelength range of 800 to 1200 nm of 0.93% (that is, 5% or less).

Furthermore, the glass substrate 101 in Example 1 has the transmittance curve in which the half-value wavelength on the short wavelength side (UV_λ50) is about 350 nm (that is, within the range of 300 to 400 nm) and the half-value wavelength on the long wavelength side (NIR_λ50) is about 599 nm (that is, within the range of 590 to 670 nm).

### [2. Formation of Resin Layer 102]

In a container, an acrylic resin (transparent resin), a styryl-based compound and a triazine-based compound (ultraviolet absorbing dye), and a squarylium-based compound (near-infrared absorbing dye) were mixed at a predetermined mixing ratio to prepare a resin film forming solution and the obtained resin film forming solution was applied onto the glass substrate 101 by using a spin coater. Then, the glass substrate 101 on which the resin film forming solution was applied was placed on a hot plate heated at 160° C. and was heated for curing for 20 minutes, thereby fabricating the near-infrared cut filter 100 in the present embodiment.

As illustrated in FIG. 3, the spectral transmittance curves (the solid line and the dashed line) of the near-infrared cut filter 100 in Example 1 are transmittance curves in which the half-value wavelength on the short wavelength side (UV_λ50) is about 413 nm, the half-value wavelength on the long wavelength side (NIR_λ50) is about 591 nm, and the average transmittance in the wavelength range of 800 to 1100 nm is 0.34%, which means that the characteristics close to the sensitivity of human visual perception were obtained.

In Example 1, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100 is 8 nm.

Since the near-infrared cut filter 100 in Example 1 does not include a reflective layer as in a near-infrared cut filter in the related art, the near-infrared cut filter 100 is inhibited from causing a phase shift, a wavelength shift, and ripples, which significantly impair the performance as a cut filter, even when light at an incident angle of 30° is incident.

### Example 2

The near-infrared cut filter 100 in Example 2 is different from that in Example 1 in that a 0.3 mm-thick fluorophosphate-based glass (CXD700) manufactured by HOYA CORPORATION was selected as the glass substrate 101 and the content of the squarylium-based compound (near-infrared absorbing dye) in the resin layer 102 was changed.

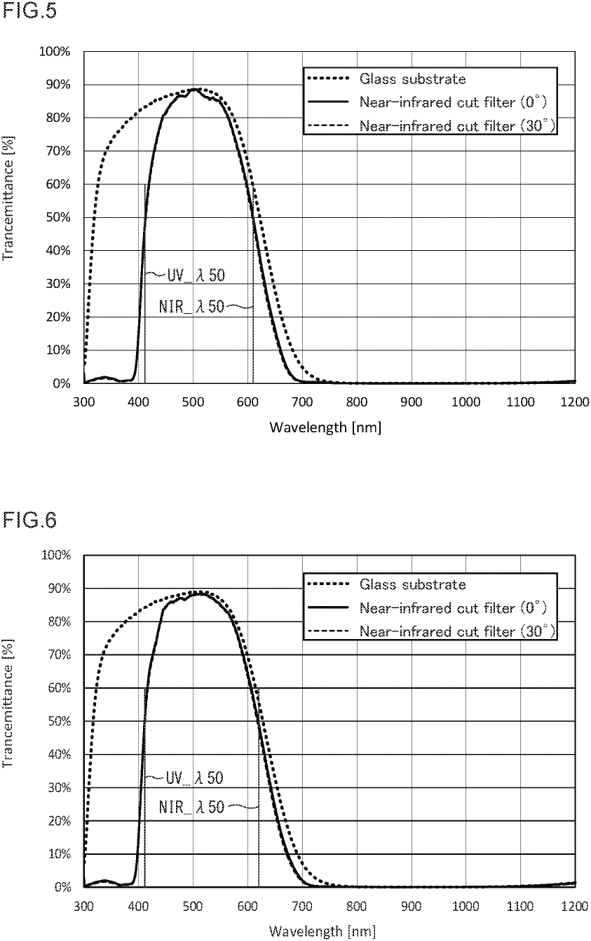

FIG. 4 is a diagram presenting a spectral transmittance curve (dotted line) of the glass substrate 101 in Example 2 and spectral transmittance curves (solid line and dashed line) of the near-infrared cut filter 100 in Example 2. As the spectral transmittance curves of the near-infrared cut filter 100, FIG. 4 presents a spectral transmittance curve (solid line) at an incident angle of 0° and a spectral transmittance curve (dashed line) at an incident angle of 30°.

As presented in FIG. 4, the glass substrate 101 in Example 2 has an average transmittance in the wavelength range of 800 to 1100 nm of 0.71% or less (that is, 1% or less).

Then, the glass substrate 101 in Example 2 has an average transmittance in the wavelength range of 720 to 750 nm of 1.26% (that is, 15% or less).

Moreover, the glass substrate 101 has an average transmittance in the wavelength range of 650 to 720 nm of 7.7% (that is, 40% or less).

Further, the glass substrate 101 has an average transmittance in the wavelength range of 800 to 1200 nm of 1.65% (that is, 5% or less).

Furthermore, the glass substrate 101 in Example 2 has the transmittance curve in which the half-value wavelength on the short wavelength side (UV_λ50) is about 348 nm (that is, within the range of 300 to 400 nm) and the half-value wavelength on the long wavelength side (NIR_λ50) is about 604 nm (that is, within the range of 590 to 670 nm).

The near-infrared cut filter 100 in Example 2 has the transmittance curves in which the half-value wavelength on the short wavelength side (UV_λ50) is about 411 nm, the half-value wavelength on the long wavelength side (NIR_λ50) is about 600 nm, and the average transmittance in the wavelength range of 800 to 1100 nm is 0.71% or less, which means that the characteristics close to the sensitivity of human visual perception were obtained.

In Example 2, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100 is 4 nm.

Since the near-infrared cut filter 100 in Example 2 also does not include a reflective layer as in a near-infrared cut filter in the related art, the near-infrared cut filter 100 is inhibited from causing a phase shift, a wavelength shift, and ripples, which significantly impair the performance as a cut filter, even when light at an incident angle of 30° is incident.

### Example 3

The near-infrared cut filter 100 in Example 3 is different from that in Example 1 in that a 0.30 mm-thick phosphate-based glass newly developed by HOYA CORPORATION (whose patent application was already filed (Japanese Patent Application No. 2020-119553 (filing date: Jul. 10, 2020)) was selected as the glass substrate 101 and the resin layer 102 was formed by using the acrylic resin (transparent resin), the styryl-based compound and the triazine-based compound (ultraviolet absorbing dye), and the squarylium-based compound and a cyanine-based compound (near-infrared absorbing dye) (in other words, the type of the near-infrared absorbing dye was changed).

FIG. 5 is a diagram presenting a spectral transmittance curve (dotted line) of the glass substrate 101 in Example 3 and spectral transmittance curves (solid line and dashed line) of the near-infrared cut filter 100 in Example 3. As the spectral transmittance curves of the near-infrared cut filter 100, FIG. 5 presents a spectral transmittance curve (solid line) at an incident angle of 0° and a spectral transmittance curve (dashed line) at an incident angle of 30°.

As presented in FIG. 5, the glass substrate 101 in Example 3 has an average transmittance in the wavelength range of 800 to 1100 nm of 0.03% (that is, 1% or less).

Then, the glass substrate 101 in Example 3 has an average transmittance in the wavelength range of 720 to 750 nm of 1.03% (that is, 15% or less).

Moreover, the glass substrate 101 in Example 3 has an average transmittance in the wavelength range of 650 to 720 nm of 11.1% (that is, 40% or less).

Further, the glass substrate 101 in Example 3 has an average transmittance in the wavelength range of 800 to 1200 nm of 0.11% (that is, 5% or less).

Furthermore, the glass substrate 101 in Example 3 has the transmittance curve in which the half-value wavelength on the short wavelength side (UV_λ50) is about 319 nm (that is, within the range of 300 to 400 nm) and the half-value wavelength on the long wavelength side (NIR_λ50) is about 622 nm (that is, within the range of 590 to 670 nm).

The near-infrared cut filter 100 in Example 3 has the transmittance curves in which the half-value wavelength on the short wavelength side (UV_λ50) is about 413 nm, the half-value wavelength on the long wavelength side (NIR_λ50) is about 610 nm, and the average transmittance in the wavelength range of 800 to 1100 nm is 0.03%, which means that the characteristics close to the sensitivity of human visual perception were obtained.

In Example 3, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100 is 12 nm.

Since the near-infrared cut filter 100 in Example 3 also does not include a reflective layer as in a near-infrared cut filter in the related art, the near-infrared cut filter 100 is inhibited from causing a phase shift, a wavelength shift, and ripples, which significantly impair the performance as a cut filter, even when light at an incident angle of 30° is incident.

### Example 4

The near-infrared cut filter 100 in Example 4 is different from that in Example 3 in that a 0.26 mm-thick glass was selected as the glass substrate 101 and the type and content of the near-infrared absorbing dye in the resin layer 102 were changed.

FIG. 6 is a diagram presenting a spectral transmittance curve (dotted line) of the glass substrate 101 in Example 4 and spectral transmittance curves (solid line and dashed line) of the near-infrared cut filter 100 in Example 4. As the spectral transmittance curves of the near-infrared cut filter 100, FIG. 6 presents a spectral transmittance curve (solid line) at an incident angle of 0° and a spectral transmittance curve (dashed line) at an incident angle of 30°.

As presented in FIG. 6, the glass substrate 101 in Example 4 has an average transmittance in the wavelength range of 800 to 1100 nm of 0.09% (that is, 1% or less).

Then, the glass substrate 101 in Example 4 has an average transmittance in the wavelength range of 720 to 750 nm of 1.85% (that is, 15% or less).

Moreover, the glass substrate 101 has an average transmittance in the wavelength range of 650 to 720 nm of 14.3% (that is, 40% or less).

Further, the glass substrate 101 has an average transmittance in the wavelength range of 800 to 1200 nm of 0.25% (that is, 5% or less).

Furthermore, the glass substrate 101 in Example 4 has the transmittance curve in which the half-value wavelength on the short wavelength side (UV_λ50) is about 317 nm (that is, within the range of 300 to 400 nm) and the half-value wavelength on the long wavelength side (NIR_λ50) is about 628 nm (that is, within the range of 590 to 670 nm).

The near-infrared cut filter 100 in Example 4 have the transmittance curves in which the half-value wavelength on the short wavelength side (UV_λ50) is about 411 nm, the half-value wavelength on the long wavelength side (NIR_λ50) is about 619 nm, and the average transmittance in the wavelength range of 800 to 1100 nm is 0.08%, which means that the characteristics close to the sensitivity of human visual perception were obtained.

In Example 4, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100 is 9 nm.

Since the near-infrared cut filter 100 in Example 4 also does not include a reflective layer as in a near-infrared cut filter in the related art, the near-infrared cut filter 100 is inhibited from causing a phase shift, a wavelength shift, and ripples, which significantly impair the performance as a cut filter, even when light at an incident angle of 30° is incident.

### Example 5

The near-infrared cut filter 100 in Example 5 is different from that in Example 3 in that a 0.25 mm-thick glass was selected as the glass substrate 101 and the type and content of the near-infrared absorbing dye in the resin layer 102 were changed.

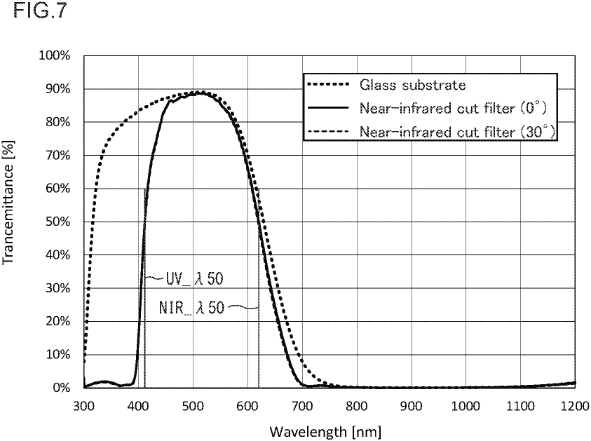

FIG. 7 is a diagram presenting a spectral transmittance curve (dotted line) of the glass substrate 101 in Example 5 and spectral transmittance curves (solid line and dashed line) of the near-infrared cut filter 100 in Example 5. As the spectral transmittance curves of the near-infrared cut filter 100, FIG. 7 presents a spectral transmittance curve (solid line) at an incident angle of 0° and a spectral transmittance curve (dashed line) at an incident angle of 30°.

As presented in FIG. 7, the glass substrate 101 in Example 5 has an average transmittance in the wavelength range of 800 to 1100 nm of 0.11% (that is, 1% or less).

Then, the glass substrate 101 in Example 5 has an average transmittance in the wavelength range of 720 to 750 nm of 2.15% (that is, 15% or less).

Moreover, the glass substrate 101 has an average transmittance in the wavelength range of 650 to 720 nm of 15.3% (that is, 40% or less).

Further, the glass substrate 101 has an average transmittance in the wavelength range of 800 to 1200 nm of 0.31% (that is, 5% or less).

Furthermore, the glass substrate 101 in Example 5 has the transmittance curve in which the half-value wavelength on the short wavelength side of (UV_λ50) is about 316 nm (that is, within the range of 300 to 400 nm) and the half-value wavelength on the long wavelength side (NIR_λ50) is about 629 nm (that is, within the range of 590 to 670 nm).

The near-infrared cut filter 100 in Example 5 has the transmittance curves in which the half-value wavelength on the short wavelength side (UV_λ50) is about 411 nm, the half-value wavelength on the long wavelength side (NIR_λ50) is about 620 nm, and the average transmittance in the wavelength range of 800 to 1100 nm is 0.31%, which means that the characteristics close to the sensitivity of human visual perception were obtained.

In Example 5, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100 is 9 nm.

Since the near-infrared cut filter 100 in Example 5 also does not include a reflective layer as in a near-infrared cut filter in the related art, the near-infrared cut filter 100 is inhibited from causing a phase shift, a wavelength shift, and ripples, which significantly impair the performance as a cut filter, even when light at an incident angle of 30° is incident.

### Example 6

The near-infrared cut filter 100 in Example 6 is different from that in Example 3 in that a 0.227 mm-thick glass was selected as the glass substrate 101 and the type and content of the near-infrared absorbing dye in the resin layer 102 were changed.

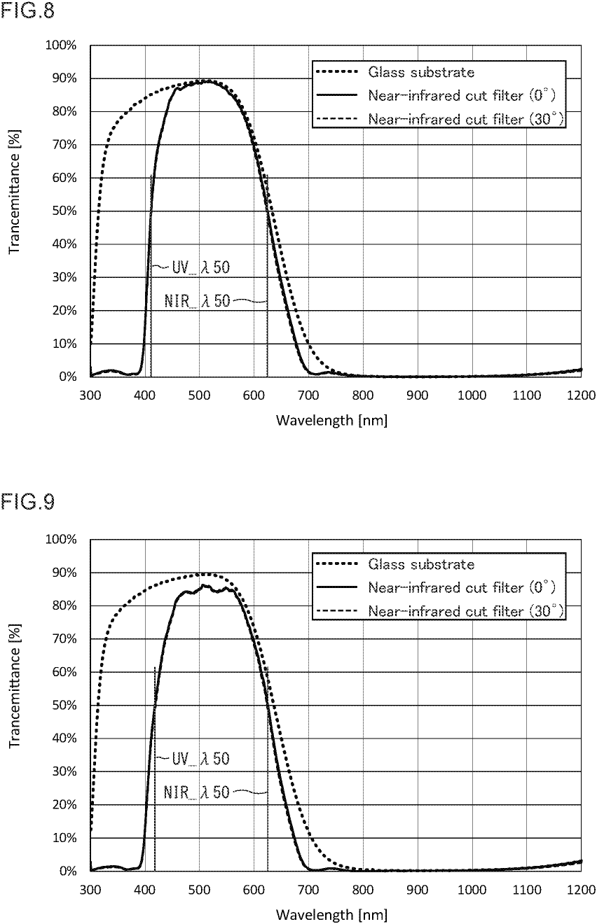

FIG. 8 is a diagram presenting a spectral transmittance curve (dotted line) of the glass substrate 101 in Example 678 and spectral transmittance curves (solid line and dashed line) of the near-infrared cut filter 100 in Example 6. As the spectral transmittance curves of the near-infrared cut filter 100, FIG. 8 presents a spectral transmittance curve (solid line) at an incident angle of 0° and a spectral transmittance curve (dashed line) at an incident angle of 30°.

As presented in FIG. 8, the glass substrate 101 in Example 6 has an average transmittance in the wavelength range of 800 to 1100 nm of 0.20% (that is, 1% or less).

Then, the glass substrate 101 in Example 6 has an average transmittance in the wavelength range of 720 to 750 nm of 3.02% (that is, 15% or less).

Moreover, the glass substrate 101 has an average transmittance in the wavelength range of 650 to 720 nm of 17.7% (that is, 40% or less).

Further, the glass substrate 101 has an average transmittance in the wavelength range of 800 to 1200 nm of 0.49% (that is, 5% or less).

Furthermore, the glass substrate 101 in Example 6 has the transmittance curve in which the half-value wavelength on the short wavelength side (UV_λ50) is about 315 nm (that is, within the range of 300 to 400 nm) and the half-value wavelength on the long wavelength side (NIR_λ50) is about 633 nm (that is, within the range of 590 to 670 nm).

The near-infrared cut filter 100 in Example 6 has the transmittance curves in which the half-value wavelength on the short wavelength side (UV_λ50) is about 411 nm, the half-value wavelength on the long wavelength side (NIR_λ50) is about 625 nm, and the average transmittance in the wavelength range of 800 to 1100 nm is 0.20%, which means that the characteristics close to the sensitivity of human visual perception were obtained.

In Example 6, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100 is 8 nm.

Since the near-infrared cut filter 100 in Example 6 also does not include a reflective layer as in a near-infrared cut filter in the related art, the near-infrared cut filter 100 is inhibited from causing a phase shift, a wavelength shift, and ripples, which significantly impair the performance as a cut filter, even when light at an incident angle of 30° is incident.

### Example 7

The near-infrared cut filter 100 in Example 7 is different from that in Example 3 in that a 0.210 mm-thick glass was selected as the glass substrate 101 and the type of the near-infrared absorbing dye in the resin layer 102 was changed to only the squarylium-based compound.

FIG. 9 is a diagram presenting a spectral transmittance curve (dotted line) of the glass substrate 101 in Example 7 and spectral transmittance curves (solid line and dashed line) of the near-infrared cut filter 100 in Example 7. As the spectral transmittance curves of the near-infrared cut filter 100, FIG. 9 presents a spectral transmittance curve (solid line) at an incident angle of 0° and a spectral transmittance curve (dashed line) at an incident angle of 30°.

As presented in FIG. 9, the glass substrate 101 in Example 7 has an average transmittance in the wavelength range of 800 to 1100 nm of 0.31% (that is, 1% or less).

Then, the glass substrate 101 in Example 7 has an average transmittance in the wavelength range of 720 to 750 nm of 3.88% (that is, 15% or less).

Moreover, the glass substrate 101 has an average transmittance in the wavelength range of 650 to 720 nm of 19.9% (that is, 40% or less).

Further, the glass substrate 101 has an average transmittance in the wavelength range of 800 to 1200 nm of 0.70% (that is, 5% or less).

Furthermore, the glass substrate 101 in Example 4 has the transmittance curve in which the half-value wavelength on the short wavelength side (UV_λ50) is about 314 nm (that is, within the range of 300 to 400 nm) and the half-value wavelength on the long wavelength side (NIR_λ50) is about 636 nm (that is, within the range of 590 to 670 nm).

The near-infrared cut filter 100 in Example 7 has the transmittance curves in which the half-value wavelength on the short wavelength side (UV_λ50) is about 418 nm, the half-value wavelength on the long wavelength side (NIR_λ50) is about 625 nm, and the average transmittance in the wavelength range of 800 to 1100 nm is 0.27%, which means that the characteristics close to the sensitivity of human visual perception were obtained.

In Example 7, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100 is 11 nm.

Since the near-infrared cut filter 100 in Example 7 also does not include a reflective layer as in a near-infrared cut filter in the related art, the near-infrared cut filter 100 is inhibited from causing a phase shift, a wavelength shift, and ripples, which significantly impair the performance as a cut filter, even when light at an incident angle of 30° is incident.

### Example 8

The near-infrared cut filter 100 in Example 8 is different from that in Example 7 in that the content of the near-infrared absorbing dye in the resin layer 102 was changed.

FIG. 10 is a diagram presenting a spectral transmittance curve (dotted line) of the glass substrate 101 in Example 8 and spectral transmittance curves (solid line and dashed line) of the near-infrared cut filter 100 in Example 8. As the spectral transmittance curves of the near-infrared cut filter 100, FIG. 10 presents a spectral transmittance curve (solid line) at an incident angle of 0° and a spectral transmittance curve (dashed line) at an incident angle of 30°.

As presented in FIG. 10, the near-infrared cut filter 100 in Example 8 has the transmittance curves in which the half-value wavelength on the short wavelength side (UV_λ50) is about 412 nm, the half-value wavelength on the long wavelength side (NIR_λ50) is about 630 nm, and the average transmittance in the wavelength range of 800 to 1100 nm is 0.29%, which means that the characteristics close to the sensitivity of human visual perception were obtained.

In Example 8, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100 is 6 nm.

Since the near-infrared cut filter 100 in Example 8 also does not include a reflective layer as in a near-infrared cut filter in the related art, the near-infrared cut filter 100 is inhibited from causing a phase shift, a wavelength shift, and ripples, which significantly impair the performance as a cut filter, even when light at an incident angle of 30° is incident.

### Example 9

The near-infrared cut filter 100 in Example 9 is different from that in Example 8 in that a 0.165 mm-thick glass was selected as the glass substrate 101 and the type and content of the near-infrared absorbing dye in the resin layer 102 were changed.

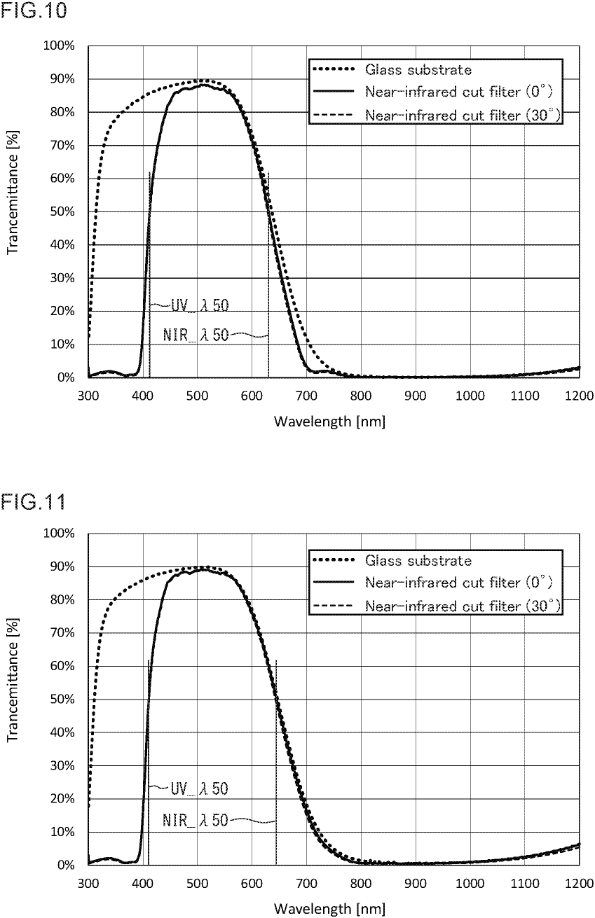

FIG. 11 is a diagram presenting a spectral transmittance curve (dotted line) of the glass substrate 101 in Example 9 and spectral transmittance curves (solid line and dashed line) of the near-infrared cut filter 100 in Example 9. As the spectral transmittance curves of the near-infrared cut filter 100, FIG. 11 presents a spectral transmittance curve (solid line) at an incident angle of 0° and a spectral transmittance curve (dashed line) at an incident angle of 30°.

As presented in FIG. 11, the glass substrate 101 in Example 9 has an average transmittance in the wavelength range of 800 to 1100 nm of 1.02% (that is, 3% or less).

Then, the glass substrate 101 in Example 9 has an average transmittance in the wavelength range of 720 to 750 nm of 7.58% (that is, 15% or less).

Moreover, the glass substrate 101 has an average transmittance in the wavelength range of 650 to 720 nm of 26.9% (that is, 40% or less).

Further, the glass substrate 101 has an average transmittance in the wavelength range of 800 to 1200 nm of 1.80% (that is, 5% or less).

Furthermore, the glass substrate 101 in Example 9 has the transmittance curve in which the half-value wavelength on the short wavelength side (UV_λ50) is about 311 nm (that is, within the range of 300 to 400 nm) and the half-value wavelength on the long wavelength side (NIR_λ50) is about 647 nm (that is, within the range of 590 to 670 nm).

The near-infrared cut filter 100 in Example 9 has the transmittance curves in which the half-value wavelength on the short wavelength side (UV_λ50) is about 410 nm, the half-value wavelength on the long wavelength side (NIR_λ50) is about 645 nm, and the average transmittance in the wavelength range of 800 to 1100 nm is 0.96%, which means that the characteristics close to the sensitivity of human visual perception were obtained.

In Example 9, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100 is 2 nm.

Since the near-infrared cut filter 100 in Example 9 also does not include a reflective layer as in a near-infrared cut filter in the related art, the near-infrared cut filter 100 is inhibited from causing a phase shift, a wavelength shift, and ripples, which significantly impair the performance as a cut filter, even when light at an incident angle of 30° is incident.

### Example 10

The near-infrared cut filter 100 in Example 10 is different from that in Example 9 in that a 0.150 mm-thick glass was selected as the glass substrate 101 and the content of the near-infrared absorbing dye in the resin layer 102 was changed.

FIG. 12 is a diagram presenting a spectral transmittance curve (dotted line) of the glass substrate 101 in Example 10 and spectral transmittance curves (solid line and dashed line) of the near-infrared cut filter 100 in Example 10. As the spectral transmittance curves of the near-infrared cut filter 100, FIG. 12 presents a spectral transmittance curve (solid line) at an incident angle of 0° and a spectral transmittance curve (dashed line) at an incident angle of 30°.

As presented in FIG. 12, the glass substrate 101 in Example 10 has an average transmittance in the wavelength range of 800 to 1100 nm of 1.52% (that is, 3% or less).

Then, the glass substrate 101 in Example 10 has an average transmittance in the wavelength range of 720 to 750 nm of 9.48% (that is, 15% or less).

Moreover, the glass substrate 101 has an average transmittance in the wavelength range of 650 to 720 nm of 29.9% (that is, 40% or less).

Further, the glass substrate 101 has an average transmittance in the wavelength range of 800 to 1200 nm of 2.50% (that is, 5% or less).

Furthermore, the glass substrate 101 in Example 10 has the transmittance curve in which the half-value wavelength on the short wavelength side (UV_λ50) is about 310 nm (that is, within the range of 300 to 400 nm) and the half-value wavelength on the long wavelength side (NIR_λ50) is about 651 nm (that is, within the range of 590 to 670 nm).

The near-infrared cut filter 100 in Example 10 has the transmittance curves in which the half-value wavelength on the short wavelength side (UV_λ50) is about 410 nm, the half-value wavelength on the long wavelength side (NIR_λ50) is about 650 nm, and the average transmittance in the wavelength range of 800 to 1100 nm is 1.46%, which means that the characteristics close to the sensitivity of human visual perception were obtained.

In Example 10, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100 is 1 nm.

Since the near-infrared cut filter 100 in Example 10 also does not include a reflective layer as in a near-infrared cut filter in the related art, the near-infrared cut filter 100 is inhibited from causing a phase shift, a wavelength shift, and ripples, which significantly impair the performance as a cut filter, even when light at an incident angle of 30° is incident.

### Example 11

The near-infrared cut filter 100 in Example 11 is different from that in Example 3 in that a 0.134 mm-thick glass was selected as the glass substrate 101 and the type of the near-infrared absorbing dye in the resin layer 102 was changed to only the cyanine-based compound.

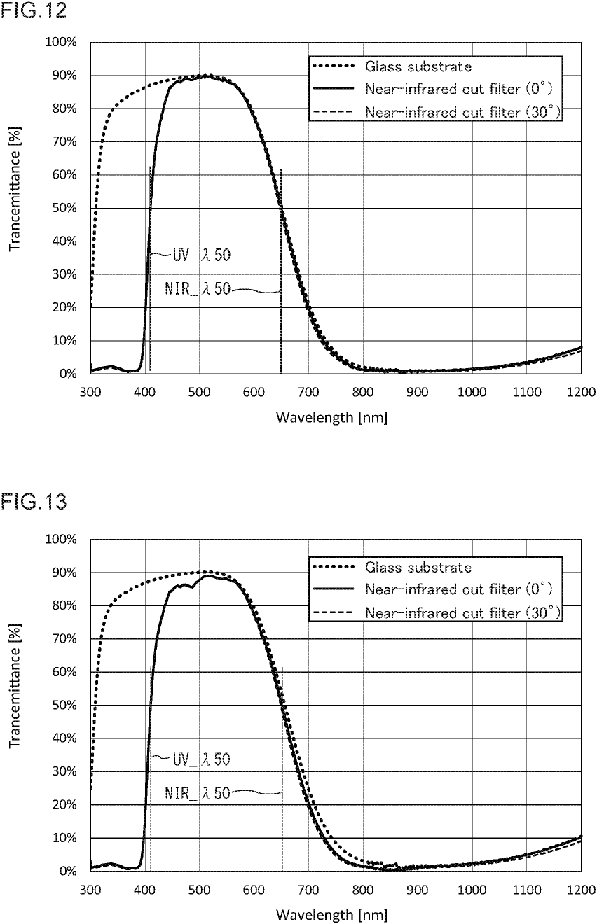

FIG. 13 is a diagram presenting a spectral transmittance curve (dotted line) of the glass substrate 101 in Example 11 and spectral transmittance curves (solid line and dashed line) of the near-infrared cut filter 100 in Example 11. As the spectral transmittance curves of the near-infrared cut filter 100, FIG. 13 presents a spectral transmittance curve (solid line) at an incident angle of 0° and a spectral transmittance curve (dashed line) at an incident angle of 30°.

As presented in FIG. 13, the glass substrate 101 in Example 11 has an average transmittance in the wavelength range of 800 to 1100 nm of 2.33% (that is, 3% or less).

Then, the glass substrate 101 in Example 11 has an average transmittance in the wavelength range of 720 to 750 nm of 12.05% (that is, 15% or less).

Moreover, the glass substrate 101 has an average transmittance in the wavelength range of 650 to 720 nm of 33.5% (that is, 40% or less).

Further, the glass substrate 101 has an average transmittance in the wavelength range of 800 to 1200 nm of 3.63% (that is, 5% or less).

Furthermore, the glass substrate 101 in Example 11 has the transmittance curve in which the half-value wavelength on the short wavelength side (UV_λ50) is about 309 nm (that is, within the range of 300 to 400 nm) and the half-value wavelength on the long wavelength side (NIR_λ50) is about 656 nm (that is, within the range of 590 to 670 nm).

The near-infrared cut filter 100 in Example 11 has the transmittance curves in which the half-value wavelength on the short wavelength side (UV_λ50) is about 410 nm, the half-value wavelength on the long wavelength side (NIR_λ50) is about 651 nm, and the average transmittance in the wavelength range of 800 to 1100 nm is 1.96%, which means that the characteristics close to the sensitivity of human visual perception were obtained.

In Example 11, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100 is 5 nm.

Since the near-infrared cut filter 100 in Example 11 also does not include a reflective layer as in a near-infrared cut filter in the related art, the near-infrared cut filter 100 is inhibited from causing a phase shift, a wavelength shift, and ripples, which significantly impair the performance as a cut filter, even when light at an incident angle of 30° is incident.

Thus, the near-infrared cut filters 100 in the present embodiment (Examples 1 to 11) obtained the characteristics close to the sensitivity of human visual perception by using the glasses each having a very low average transmittance in the wavelength range of 800 to 1100 nm (that is, 3% or less or 1% or less) as the glass substrate 101 without using a reflective layer as in the related art.

Therefore, the near-infrared cut filters 100 in the present embodiment have extremely low incident angle dependence and excellent oblique incidence characteristics. In addition, the imaging device 1 using the near-infrared cut filter 100 as described above is capable of obtaining images excellent in color reproducibility because the occurrence of ghost is suppressed.

The above description is provided for explaining the embodiment of the present invention, but the present invention should not be limited to the structure of the aforementioned embodiment, but may be modified in various ways within the scope of the technical idea.

For example, the present embodiment (Examples 1 to 11) illustrates the near-infrared cut filters 100 having the transmittance curves in which the half-value wavelength on the short wavelength side (UV_λ50) is about 410 to 418 nm, and the half-value wavelength on the long wavelength side (NIR_λ50) is about 591 to 651 nm, but embodiments should not be limited to filters having such characteristics. In the transmittance curve, the half-value wavelength on the short wavelength side can be adjusted within a range of 385 to 430 nm and the half-value wavelength on the long wavelength side can be adjusted within a range of 590 to 670 nm by selecting an ultraviolet absorbing dye and a near-infrared absorbing dye for the resin layer 102 as appropriate and adjusting the mixing ratio of them.

### Second Embodiment

FIG. 14 is a vertical cross-sectional view for explaining a structure of a near-infrared cut filter 100A according to a second embodiment of the present invention. As illustrated in FIG. 14, the near-infrared cut filter 100A in the present embodiment is different from the near-infrared cut filter 100 in the first embodiment in that the near-infrared cut filter 100A includes an anti-reflective film 103 (first anti-reflective film) on the upper surface of the resin layer 102 (the surface opposite to the glass substrate 101) and an anti-reflective film 104 (second anti-reflective film) on the other main surface of the glass substrate 101 (the lower surface in FIG. 14).

The formation of the anti-reflective films 103 and 104 as described above makes it possible to suppress reflection at the boundaries (that is, the incident surface and the exit surface) of the near-infrared cut filter 100A and thereby enhance (improve) the transmittance.

The anti-reflective films 103 and 104 of the present embodiment are layers that prevent reflection at the boundaries on the incident surface and the exit surface of the near-infrared cut filter 100A and are specifically each composed of a dielectric multilayer film in which dielectric films having a low refractive index (low refractive index dielectric films) and dielectric films having a high refractive index (high refractive index dielectric films) are alternately stacked.

Materials for the dielectric films constituting the dielectric multilayer film can be freely selected according to desired optical characteristics. However, the refractive index of a low refractive index material for forming dielectric films having a low refractive index is preferably in a range of 1.1 to 1.5. For example, SiO₂, MgF₂, and SiO₂ hollow particles, a low refractive index sol-gel coat having an aerosol structure, and the like may be applied as the low refractive index material. Meanwhile, the refractive index of a high refractive index material for forming dielectric films having a high refractive index is preferably in a range of 2.0 to 2.5. For example, ZrO₂, Ta₂O₅, TiO₂, Nb₂O₅, and the like may be applied as the high refractive index material.

In addition, a material having a refractive index of 1.4 to 1.6 (for example, SiO₂) may be used as the high refractive index material. In this case, a material having a refractive index of 1.1 to 1.3 (for example, aerosol coat) may be applied as the low refractive index material.

The use of the dielectric multilayer films for the anti-reflective films 103 and 104 as described above makes it possible to easily impart an anti-reflective function by utilizing interference of light that occurs in each of the dielectric films. However, when the number of film layers increases, the optical path length in oblique incidence of light is so long that the interference conditions of the reflected light in each layer deviate to cause problems such as the occurrence of a wavelength shift and ripples. Moreover, such wavelength shift and ripples lead to an increase in the reflected light and are observed as a kind of ghost on the solid-state image sensor 200, which also causes a problem that the accurate color reproducibility cannot be obtained. To avoid these problems, in the present embodiment, the dielectric multilayer film is structured such that the number of film layers is 10 or less. In particular, the number of film layers is preferably 5 or less and more preferably 3 or less.

The thickness of each dielectric film constituting the dielectric multilayer film can be freely selected according to desired optical characteristics, but is preferably 50 nm to 1 µm and more preferably 50 nm to 500 nm.

The thickness of the entire dielectric multilayer film (that is, the anti-reflective film 103 or 104) is set to 500 nm or less.

The resin layer 102 in the present embodiment is formed on one main surface of the glass substrate 101 (the upper surface in FIG. 14), but the resin layer 102 may be formed on the other main surface (the lower surface in FIG. 14) of the glass substrate 101 as in the first embodiment, or the resin layers 102 may be formed on both surfaces of the glass substrate 101. Moreover, the resin layer 102 does not necessarily have to be a single layer, and may be composed of multiple layers.

Although the near-infrared cut filter 100A has the structure provided with the anti-reflective films 103 and 104 in the present embodiment, embodiments are not limited to this structure. In place of the anti-reflective films 103 and 104, optical thin films having different functions of an infrared cut film, an ultraviolet cut film, and so on may be used. In other words, the near-infrared cut filter 100A according to the present embodiment may include optical films having at least one or more of functions of an anti-reflective film, an infrared cut film, and an ultraviolet cut film.

Hereinafter, the near-infrared cut filter 100A in the present embodiment will be further described by using Examples, but the present invention should not be limited to Examples below.

### Example 12

The near-infrared cut filter 100A in Example 12 was fabricated by further forming the anti-reflective films 103 and 104 on the near-infrared cut filter 100 in Example 1 in the following procedure (3. Formation of Anti-reflective Films 103 and 104).

### [3. Formation of Anti-Reflective Films 103 and 104]

Using a so-called sol-gel method, dielectric thin films (dielectric layers 1 to 5) specified in Table 1 were sequentially formed (in short, the anti-reflective films 103 and 104 were formed) on the upper surface (the surface opposite to the glass substrate 101) of the resin layer 102 and the other main surface (the lower surface in FIG. 14) of the glass substrate 101 in the near-infrared cut filter 100 in Example 1, so that the near-infrared cut filter 100A in Example 12 was obtained.

TABLE 1

| | Thickness (nm) | Refractive Index | Material |
|---|---|---|---|
| Dielectric Layer 5 | 85 | 1.48 | SiO₂ |
| Dielectric Layer 4 | 107 | 2.42 | TiO₂ |
| Dielectric Layer 3 | 35 | 1.48 | SiO₂ |
| Dielectric Layer 2 | 11 | 2.42 | TiO₂ |
| Dielectric Layer 1 | 98 | 1.48 | SiO₂ |
| Glass | | 1.52 | Phosphate/Fluorophosphate |

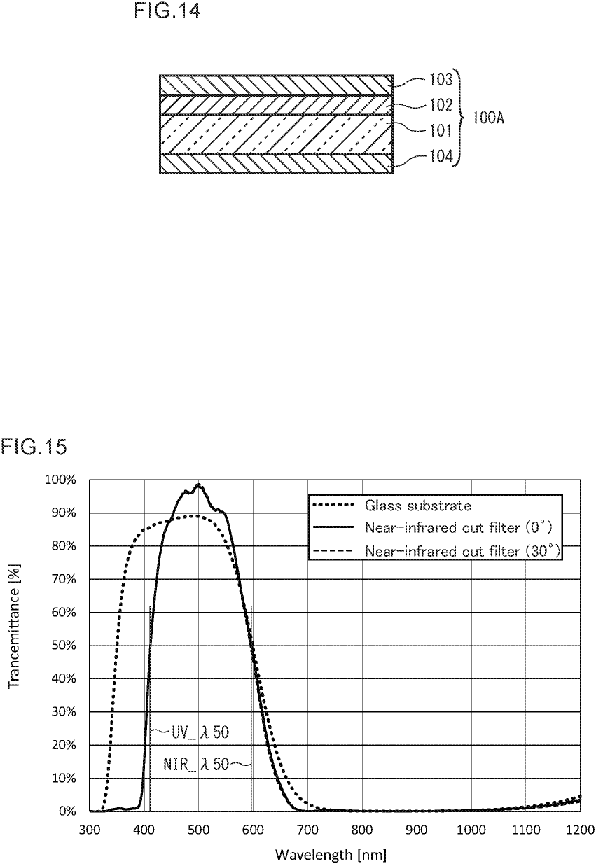

FIG. 15 is a diagram presenting spectral transmittance curves of the near-infrared cut filter 100A in Example 12 and presents a spectral transmittance curve (solid line) at an incident angle of 0° and a spectral transmittance curve (dashed line) at an incident angle of 30°. As presented in FIG. 15, the near-infrared cut filter 100A in Example 12 has the transmittance curves in which the half-value wavelength on the short wavelength side (UV_λ50) is about 411 nm, the half-value wavelength on the long wavelength side (NIR_λ50) is about 596 nm, and the average transmittance in the wavelength range of 800 to 1100 nm is 0.3%, which means that the characteristics close to the sensitivity of human visual perception were obtained.

In Example 12, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100A is 3 nm.

Although the near-infrared cut filter 100A in Example 12 includes the dielectric multilayer films as the anti-reflective films 103 and 104, the thickness is sufficiently thin (500 nm or less). For this reason, the near-infrared cut filter 100A is inhibited from causing a phase shift, a wavelength shift, and ripples, which significantly impair the performance as a cut filter, even when light at an incident angle of 30° is incident.

In addition, including the anti-reflective films 103 and 104, the near-infrared cut filter 100A in Example 12 has a higher transmittance than that of the near-infrared cut filter 100 in Example 1 (i.e., than in FIG. 3) and has a peak of the transmittance of about 98%.

### Example 13

The near-infrared cut filter 100A in Example 13 was fabricated by forming the anti-reflective films 103 and 104 on the near-infrared cut filter 100 in Example 2 in the same procedure as in Example 12.

FIG. 16 is a diagram presenting spectral transmittance curves of the near-infrared cut filter 100A in Example 13 and presents a spectral transmittance curve (solid line) at an incident angle of 0° and a spectral transmittance curve (dashed line) at an incident angle of 30°. As presented in FIG. 16, the near-infrared cut filter 100A in Example 13 has the transmittance curves in which the half-value wavelength on the short wavelength side (UV_λ50) is about 410 nm, the half-value wavelength on the long wavelength side (NIR_λ50) is about 605 nm, the average transmittance in the wavelength range of 800 to 1100 nm is 0.6%, which means that the characteristics close to the sensitivity of human visual perception were obtained.

In Example 13, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100A is 1 nm.

Although the near-infrared cut filter 100A in Example 13 includes the dielectric multilayer films as the anti-reflective films 103 and 104, the thickness is sufficiently thin (500 nm or less). For this reason, the near-infrared cut filter 100A is inhibited from causing a phase shift, a wavelength shift, and ripples, which significantly impair the performance as a cut filter, even when light at an incident angle of 30° is incident.

In addition, including the anti-reflective films 103 and 104, the near-infrared cut filter 100A in Example 13 has a higher transmittance than that of the near-infrared cut filter 100 in Example 2 (i.e., than in FIG. 4) and has a peak of the transmittance of about 97%.

### Example 14

The near-infrared cut filter 100A in Example 14 was fabricated by forming the anti-reflective films 103 and 104 on the near-infrared cut filter 100 in Example 3 in the same procedure as in Example 12.

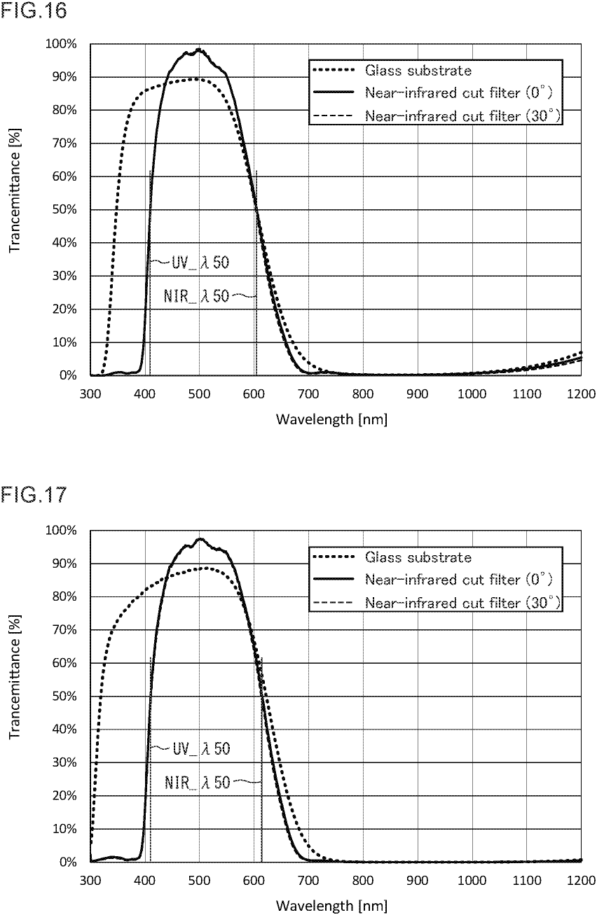

FIG. 17 is a diagram presenting spectral transmittance curves of the near-infrared cut filter 100A in Example 14 and presents a spectral transmittance curve (solid line) at an incident angle of 0° and a spectral transmittance curve (dashed line) at an incident angle of 30°. As presented in FIG. 17, the near-infrared cut filter 100A in Example 14 has the transmittance curves in which the half-value wavelength on the short wavelength side (UV_λ50) is about 410 nm, the half-value wavelength on the long wavelength side (NIR_λ50) is about 615 nm, and the average transmittance in the wavelength range of 800 to 1100 nm is 0.03%, which means that the characteristics close to the sensitivity of human visual perception were obtained.

In Example 14, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100A is 7 nm.

Although the near-infrared cut filter 100A in Example 14 includes the dielectric multilayer films as the anti-reflective films 103 and 104, the thickness is sufficiently thin (500 nm or less). For this reason, the near-infrared cut filter 100A is inhibited from causing a phase shift, a wavelength shift, and ripples, which significantly impair the performance as a cut filter, even when light at an incident angle of 30° is incident.

In addition, including the anti-reflective films 103 and 104, the near-infrared cut filter 100A in Example 14 has a higher transmittance than that of the near-infrared cut filter 100 in Example 3 (i.e., than in FIG. 5) and has a peak of the transmittance of about 97%.

### Example 15

The near-infrared cut filter 100A in Example 15 was fabricated by forming the anti-reflective films 103 and 104 on the near-infrared cut filter 100 in Example 4 in the same procedure as in Example 12.

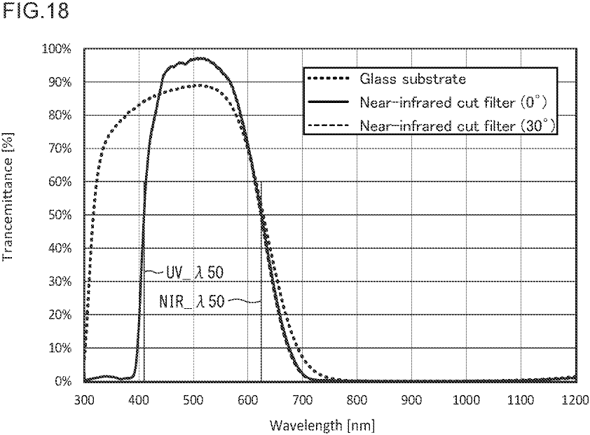

FIG. 18 is a diagram presenting spectral transmittance curves of the near-infrared cut filter 100A in Example 15 and presents a spectral transmittance curve (solid line) at an incident angle of 0° and a spectral transmittance curve (dashed line) at an incident angle of 30°. As presented in FIG. 18, the near-infrared cut filter 100A in Example 15 has the transmittance curves in which the half-value wavelength on the short wavelength side (UV_λ50) is about 409 nm, the half-value wavelength on the long wavelength side (NIR_λ50) is about 625 nm, and the average transmittance in the wavelength range of 800 to 1100 nm is 0.07%, which means that the characteristics close to the sensitivity of human visual perception were obtained.

In Example 15, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100A is 3 nm.

Although the near-infrared cut filter 100A in Example 15 includes the dielectric multilayer films as the anti-reflective films 103 and 104, the thickness is sufficiently thin (500 nm or less). For this reason, the near-infrared cut filter 100A is inhibited from causing a phase shift, a wavelength shift, and ripples, which significantly impair the performance as a cut filter, even when light at an incident angle of 30° is incident.

In addition, including the anti-reflective films 103 and 104, the near-infrared cut filter 100A in Example 15 has a higher transmittance than that of the near-infrared cut filter 100 in Example 4 (i.e., than in FIG. 6) and has a peak of the transmittance of about 97%.

### Example 16

The near-infrared cut filter 100A in Example 16 was fabricated by forming the anti-reflective films 103 and 104 on the near-infrared cut filter 100 in Example 5 in the same procedure as in Example 12.

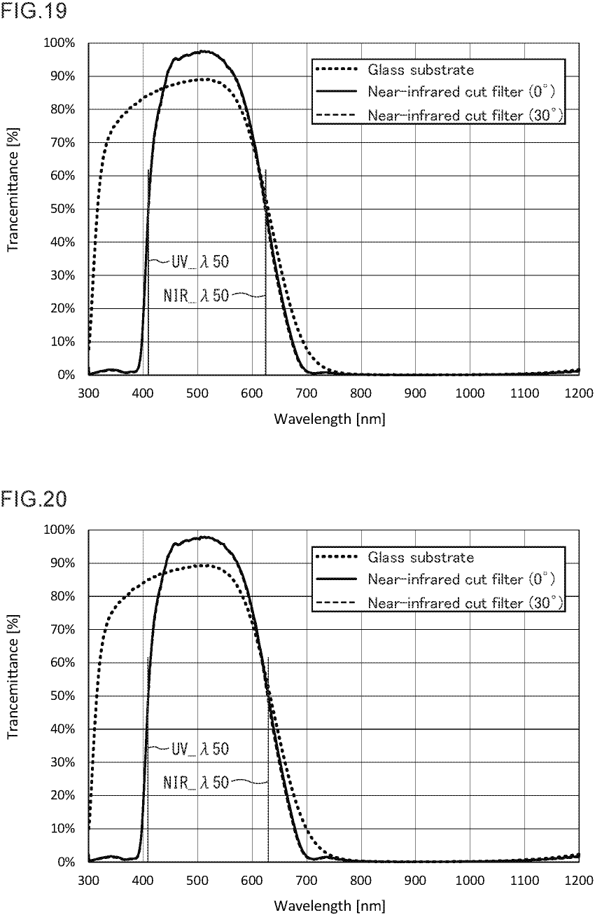

FIG. 19 is a diagram presenting spectral transmittance curves of the near-infrared cut filter 100A in Example 16 and presents a spectral transmittance curve (solid line) at an incident angle of 0° and a spectral transmittance curve (dashed line) at an incident angle of 30°. As presented in FIG. 19, the near-infrared cut filter 100A in Example 16 has the transmittance curves in which the half-value wavelength on the short wavelength side (UV_λ50) is about 410 nm, the half-value wavelength on the long wavelength side (NIR_λ50) is about 625 nm, and the average transmittance in the wavelength range of 800 to 1100 nm is 0.09%, which means that the characteristics close to the sensitivity of human visual perception were obtained.

In Example 16, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100A is 4 nm.

Although the near-infrared cut filter 100A in Example 16 includes the dielectric multilayer films as the anti-reflective films 103 and 104, the thickness is sufficiently thin (500 nm or less). For this reason, the near-infrared cut filter 100A is inhibited from causing a phase shift, a wavelength shift, and ripples, which significantly impair the performance as a cut filter, even when light at an incident angle of 30° is incident.

In addition, including the anti-reflective films 103 and 104, the near-infrared cut filter 100A in Example 16 has a higher transmittance than that of the near-infrared cut filter 100 in Example 5 (i.e., than in FIG. 7) and has a peak of the transmittance of about 98%.

### Example 17

The near-infrared cut filter 100A in Example 17 was fabricated by forming the anti-reflective films 103 and 104 on the near-infrared cut filter 100 in Example 6 in the same procedure as in Example 12.

FIG. 20 is a diagram presenting spectral transmittance curves of the near-infrared cut filter 100A in Example 17 and presents a spectral transmittance curve (solid line) at an incident angle of 0° and a spectral transmittance curve (dashed line) at an incident angle of 30°. As presented in FIG. 20, the near-infrared cut filter 100A in Example 17 has the transmittance curves in which the half-value wavelength on the short wavelength side (UV_λ50) is about 409 nm, the half-value wavelength on the long wavelength side (NIR_λ50) is about 630 nm, and the average transmittance in the wavelength range of 800 to 1100 nm is 0.2%, which means that the characteristics close to the sensitivity of human visual perception were obtained.

In Example 17, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100A is 3 nm.

Although the near-infrared cut filter 100A in Example 17 includes the dielectric multilayer films as the anti-reflective films 103 and 104, the thickness is sufficiently thin (500 nm or less). For this reason, the near-infrared cut filter 100A is inhibited from causing a phase shift, a wavelength shift, and ripples, which significantly impair the performance as a cut filter, even when light at an incident angle of 30° is incident.

In addition, including the anti-reflective films 103 and 104, the near-infrared cut filter 100A in Example 17 has a higher transmittance than that of the near-infrared cut filter 100 in Example 6 (i.e., than in FIG. 8) and has a peak of the transmittance of about 98%.

### Example 18

The near-infrared cut filter 100A in Example 18 was fabricated by forming the anti-reflective films 103 and 104 on the near-infrared cut filter 100 in Example 7 in the same procedure as in Example 12.

FIG. 21 is a diagram presenting spectral transmittance curves of the near-infrared cut filter 100A in Example 18 and presents a spectral transmittance curve (solid line) at an incident angle of 0° and a spectral transmittance curve (dashed line) at an incident angle of 30°. As presented in FIG. 21, the near-infrared cut filter 100A in Example 18 has the transmittance curves in which the half-value wavelength on the short wavelength side (UV_λ50) is about 414 nm, the half-value wavelength on the long wavelength side (NIR_λ50) is about 630 nm, and the average transmittance in the wavelength range of 800 to 1100 nm is 0.2%, which means that the characteristics close to the sensitivity of human visual perception were obtained.

In Example 18, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100A is 6 nm.

Although the near-infrared cut filter 100A in Example 18 includes the dielectric multilayer films as the anti-reflective films 103 and 104, the thickness is sufficiently thin (500 nm or less). For this reason, the near-infrared cut filter 100A is inhibited from causing a phase shift, a wavelength shift, and ripples, which significantly impair the performance as a cut filter, even when light at an incident angle of 30° is incident.

In addition, including the anti-reflective films 103 and 104, the near-infrared cut filter 100A in Example 18 has a higher transmittance than that of the near-infrared cut filter 100 in Example 7 (i.e., than in FIG. 9) and has a peak of the transmittance of about 95%.

### Example 19

The near-infrared cut filter 100A in Example 19 was fabricated by forming the anti-reflective films 103 and 104 on the near-infrared cut filter 100 in Example 8 in the same procedure as in Example 12.

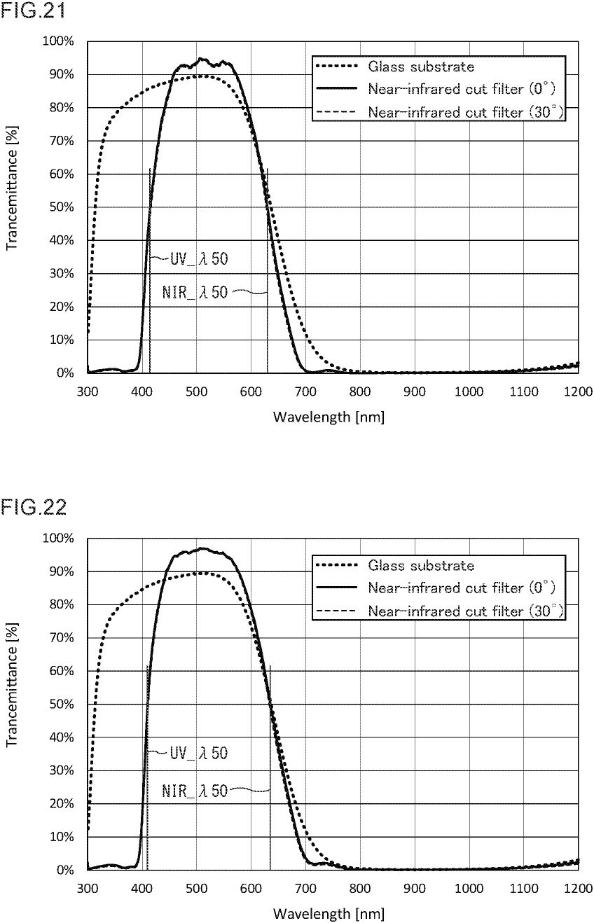

FIG. 22 is a diagram presenting spectral transmittance curves of the near-infrared cut filter 100A in Example 19 and presents a spectral transmittance curve (solid line) at an incident angle of 0° and a spectral transmittance curve (dashed line) at an incident angle of 30°. As presented in FIG. 22, the near-infrared cut filter 100A in Example 19 has the transmittance curves in which the half-value wavelength on the short wavelength side (UV_λ50) is about 410 nm, the half-value wavelength on the long wavelength side (NIR_λ50) is about 635 nm, and the average transmittance in the wavelength range of 800 to 1100 nm is 0.2%, which means that the characteristics close to the sensitivity of human visual perception were obtained.

In Example 19, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100A is 1 nm.

Although the near-infrared cut filter 100A in Example 19 includes the dielectric multilayer films as the anti-reflective films 103 and 104, the thickness is sufficiently thin (500 nm or less). For this reason, the near-infrared cut filter 100A is inhibited from causing a phase shift, a wavelength shift, and ripples, which significantly impair the performance as a cut filter, even when light at an incident angle of 30° is incident.

In addition, including the anti-reflective films 103 and 104, the near-infrared cut filter 100A in Example 19 has a higher transmittance than that of the near-infrared cut filter 100 in Example 8 (i.e., than in FIG. 10) and has a peak of the transmittance of about 97%.

### Example 20

The near-infrared cut filter 100A in Example 20 was fabricated by forming the anti-reflective films 103 and 104 on the near-infrared cut filter 100 in Example 9 in the same procedure as in Example 12.

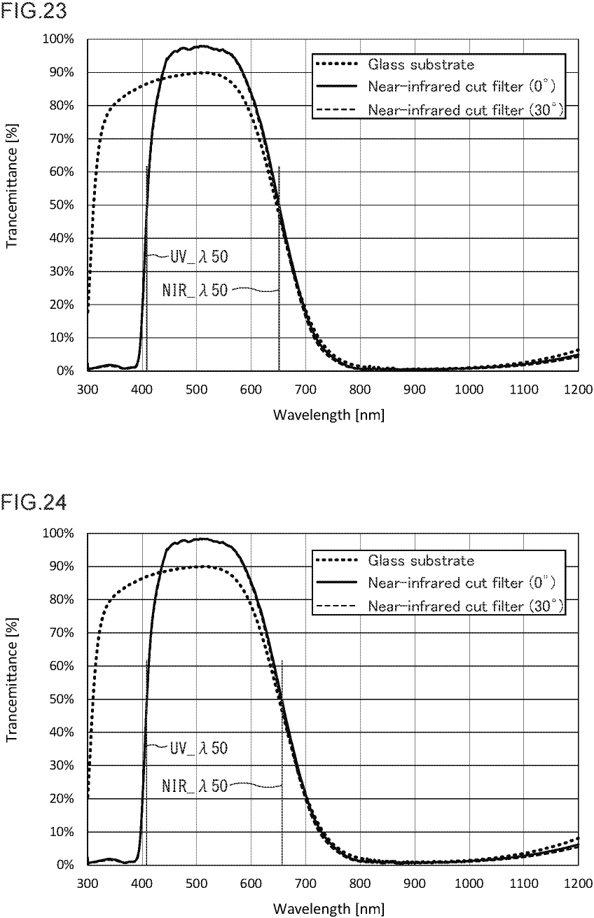

FIG. 23 is a diagram presenting spectral transmittance curves of the near-infrared cut filter 100A in Example 20 and presents a spectral transmittance curve (solid line) at an incident angle of 0° and a spectral transmittance curve (dashed line) at an incident angle of 30°. As presented in FIG. 23, the near-infrared cut filter 100A in Example 20 has the transmittance curves in which the half-value wavelength on the short wavelength side (UV_λ50) is about 409 nm, the half-value wavelength on the long wavelength side (NIR_λ50) is about 651 nm, and the average transmittance in the wavelength range of 800 to 1100 nm is 0.8%, which means that the characteristics close to the sensitivity of human visual perception were obtained.

In Example 20, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100A is 4 nm.

Although the near-infrared cut filter 100A in Example 20 includes the dielectric multilayer films as the anti-reflective films 103 and 104, the thickness is sufficiently thin (500 nm or less). For this reason, the near-infrared cut filter 100A is inhibited from causing a phase shift, a wavelength shift, and ripples, which significantly impair the performance as a cut filter, even when light at an incident angle of 30° is incident.

In addition, including the anti-reflective films 103 and 104, the near-infrared cut filter 100A in Example 20 has a higher transmittance than that of the near-infrared cut filter 100 in Example 9 (i.e., than in FIG. 11) and has a peak of the transmittance of about 98%.

### Example 21

The near-infrared cut filter 100A in Example 21 was fabricated by forming the anti-reflective films 103 and 104 on the near-infrared cut filter 100 in Example 10 in the same procedure as in Example 12.

FIG. 24 is a diagram presenting spectral transmittance curves of the near-infrared cut filter 100A in Example 21 and presents a spectral transmittance curve (solid line) at an incident angle of 0° and a spectral transmittance curve (dashed line) at an incident angle of 30°. As presented in FIG. 24, the near-infrared cut filter 100A in Example 21 has the transmittance curves in which the half-value wavelength on the short wavelength side (UV_λ50) is about 408 nm, the half-value wavelength on the long wavelength side (NIR_λ50) is about 656 nm, and the average transmittance in the wavelength range of 800 to 1100 nm is 1.3%, which means that the characteristics close to the sensitivity of human visual perception were obtained.

In Example 21, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100A is 5 nm.

Although the near-infrared cut filter 100A in Example 21 includes the dielectric multilayer films as the anti-reflective films 103 and 104, the thickness is sufficiently thin (500 nm or less). For this reason, the near-infrared cut filter 100A is inhibited from causing a phase shift, a wavelength shift, and ripples, which significantly impair the performance as a cut filter, even when light at an incident angle of 30° is incident.

In addition, including the anti-reflective films 103 and 104, the near-infrared cut filter 100A in Example 21 has a higher transmittance than that of the near-infrared cut filter 100 in Example 10 (i.e., than in FIG. 12) and has a peak of the transmittance of about 98%.

### Example 22

The near-infrared cut filter 100A in Example 22 was fabricated by forming the anti-reflective films 103 and 104 on the near-infrared cut filter 100 in Example 11 in the same procedure as in Example 12.

FIG. 25 is a diagram presenting spectral transmittance curves of the near-infrared cut filter 100A in Example 22 and presents a spectral transmittance curve (solid line) at an incident angle of 0° and a spectral transmittance curve (dashed line) at an incident angle of 30°. As presented in FIG. 25, the near-infrared cut filter 100A in Example 22 has the transmittance curves in which the half-value wavelength on the short wavelength side (UV_λ50) is about 409 nm, the half-value wavelength on the long wavelength side (NIR_λ50) is about 657 nm, and the average transmittance in the wavelength range of 800 to 1100 nm is 1.7%, which means that the characteristics close to the sensitivity of human visual perception were obtained.

In Example 22, a difference between the half-value wavelength on the long wavelength side (NIR_λ50) in the transmittance curve of the glass substrate 101 and the half-value wavelength on the long wavelength side (NIR_λ50) in the transmittance curves of the near-infrared cut filter 100A is 1 nm.

Although the near-infrared cut filter 100A in Example 22 includes the dielectric multilayer films as the anti-reflective films 103 and 104, the thickness is sufficiently thin (500 nm or less). For this reason, the near-infrared cut filter 100A is inhibited from causing a phase shift, a wavelength shift, and ripples, which significantly impair the performance as a cut filter, even when light at an incident angle of 30° is incident.

In addition, including the anti-reflective films 103 and 104, the near-infrared cut filter 100A in Example 22 has a higher transmittance than that of the near-infrared cut filter 100 in Example 11 (i.e., than in FIG. 13) and has a peak of the transmittance of about 98%.

As described above, the near-infrared cut filters 100A in Examples 12 to 22 have excellent oblique incidence characteristics and high transmittance. In addition, the imaging device 1 using the near-infrared cut filter 100A as described above is capable of obtaining images blight and also excellent in color reproducibility.

### Third Embodiment

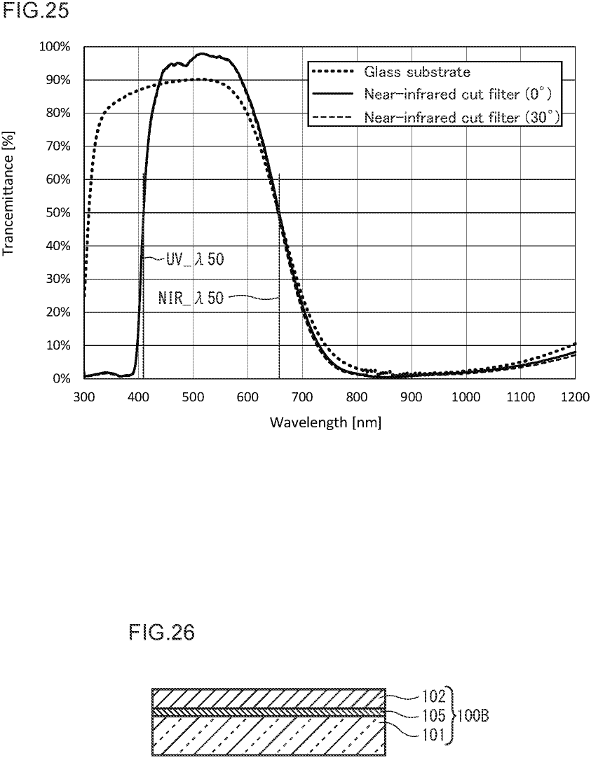

FIG. 26 is a vertical cross-sectional view for explaining a structure of a near-infrared cut filter 100B according to a third embodiment of the present invention. As illustrated in FIG. 26, the near-infrared cut filter 100B in the present embodiment is different from the near-infrared cut filter 100 in the first embodiment in that a bonding layer 105 for bonding the glass substrate 101 and the resin layer 102 is provided between the glass substrate 101 and the resin layer 102.

When the bonding layer 105 is formed as described above, the adhesion between the glass substrate 101 and the resin layer 102 can be enhanced and accordingly the reliability can be improved.

As a result of earnest studies, the inventors found that use of bonding components including Si atoms and one or more kinds selected from Ti atoms, Zr atoms, and Al atoms makes it possible to enhance the adhesion between the glass substrate 101 and the resin layer 102. The bonding layer 105 in the present embodiment is based on the above findings and has a single-layer structure containing one or more kinds selected from Ti atoms, Zr atoms, and Al atoms together with Si atoms.

In the present description, the single-layer structure means a layer structure identified, as consisting of a forming material having a homogeneous composition, from a measurement image (image contrast) or a result of elemental analysis obtained by measurement with a scanning transmission electron microscope-energy dispersive X-ray spectrometer (STEM-EDX) under the following measurement conditions.

### <Measurement Connections>

Scanning transmission electron microscope: ARM200F manufactured by JEOL Ltd.
Energy dispersive X-ray spectrometer: JED-2300T manufactured by JEOL Ltd.
Sample preparation: focused ion beam processing (FIB)
Accelerating voltage: 200 kV
Elemental analysis: EDX mapping (resolution: 256×256)

The thickness of the bonding layer 105 is preferably 1000 nm or less, more preferably 10 to 500 nm, and further preferably 30 to 300 nm.

The thickness of the bonding layer 105 of 1000 nm or less makes it easy to suppress the occurrence of unevenness in the bonding layer 105 during formation (during firing), and makes it possible to easily uniform the film surface of the bonding layer 105.

The thickness of the bonding layer 105 of 10 nm or more allows the bonding layer 105 to easily exhibit sufficient bonding strength, and thereby makes it possible to easily improve the mechanical strength of the near-infrared cut filter 100B.

In the present description, the thickness of the bonding layer 105 means an arithmetic mean value of the thickness of the bonding layer 105 measured at 50 points in a measurement image (image contrast) of a cross section of the near-infrared cut filter 100B obtained by measurement using the above STEM-EDX.

The bonding layer 105 in the present embodiment contains one or more kinds selected from Ti atoms, Zr atoms, and Al atoms together with Si atoms, and the one or more kinds contained in the bonding layer 105 together with Si atom and selected from Ti atoms, Zr atoms, and Al atoms are preferably Ti atoms.

In the bonding layer 105 in the present embodiment, a percentage α (atomic%) of the total number of Ti atoms, Zr atoms, and Al atoms to the total number (total number of atoms) of Si atoms, Ti atoms, Zr atoms, and Al atoms is preferably more than 0 atomic% to 50 atomic% or less, more preferably 9 to 50 atomic%, and further preferably 12 to 50 atomic%. In the present description, the percentage α (atomic%) of the total number of Ti atoms, Zr atoms, and Al atoms to the total number (total number of atoms) of Si atoms, Ti atoms, Zr atoms, and Al atoms constituting the bonding layer 105 means a value calculated according to the following method.

Under the above measurement conditions, STEM-EDX measurement of an optical filter is performed to obtain STEM-EDX lines (EDX-ray (K-line)-detected intensity lines in the depth direction of the respective elements constituting the optical filter).

In a region constituting the bonding layer 105, an integrated EDX-ray intensity X_{Si} of Si atoms, an integrated EDX-ray intensity X_{Ti} of Ti atoms, an integrated EDX-ray intensity X_{Zr} of Zr atoms, and an integrated EDX-ray intensity X_{Al} of Al atoms are obtained.

The value obtained by multiplying each integrated EDX-ray intensity obtained in (2) by a k factor (a correction factor which is dependent on the accelerating voltage and detection efficiency and differs for each atomic number. Hereinafter, K_{Si} denotes the k factor of Si atoms, K_{Ti} denotes the k factor of Ti atoms, K_{Zr} denotes the k factor of Zr atoms, and K_{Al} denotes the k factor of Al atoms for convenience) can be regarded as corresponding to a weight ratio among the constituent elements. Thus, for example, a weight ratio A_{Ti} (% by weight) of Ti atoms constituting the bonding layer can be calculated in accordance with the following formula.

$${\text{A}}_{\text{Ti}} = \frac{\left({\text{X}}_{\text{Ti}} \times {\text{K}}_{\text{Ti}}\right)}{\left({\text{X}}_{\text{Si}} \times {\text{K}}_{\text{Si}}\right) + \left({\text{X}}_{\text{Ti}} \times {\text{K}}_{\text{Ti}}\right) + \left({\text{X}}_{\text{Zr}} \times {\text{K}}_{\text{Zr}}\right) + \left({\text{X}}_{\text{Al}} \times {\text{K}}_{\text{Al}}\right)} \times 100 \qquad \text{[Formula 1]}$$

In addition, when the value obtained by multiplying the integrated EDX-ray intensity of each kind of atoms by the k factor is divided by an atomic weight M of the concerned kind of atoms, the obtained value can be regarded as corresponding to a ratio among the numbers of atoms of the constituent elements. Thus, when M_{Si} denotes an atomic weight of Si atoms, M_{Ti} denotes an atomic weight of Ti atoms, M_{Zr} denotes an atomic weight of Zr atoms, and M_{Al} denotes an atomic weight of Al atoms, the percentage α_{Ti} (atomic%) of the number of Ti atoms constituting the bonding layer 105, for example, can be calculated in accordance with the following formula.

$${α}_{\text{Ti}} = \frac{\left({\text{X}}_{\text{Ti}} \times {\text{K}}_{\text{Ti}} \div {\text{M}}_{\text{Ti}}\right)}{\left({\text{X}}_{\text{Si}} \times {\text{K}}_{\text{Si}} \div {\text{M}}_{\text{Si}}\right) + \left({\text{X}}_{\text{Ti}} \times {\text{K}}_{\text{Ti}} \div {\text{M}}_{\text{Ti}}\right) + \left({\text{X}}_{\text{Zr}} \times {\text{K}}_{\text{Zr}} \div {\text{M}}_{\text{Zr}}\right) + \left({\text{X}}_{\text{Al}} \times {\text{K}}_{\text{Al}} \div {\text{M}}_{\text{Al}}\right)} \times 100 \qquad \text{[Formula 2]}$$

The percentage α (atomic%) of the total number of Ti atoms, Zr atoms, and Al atoms constituting the bonding layer 105 can be calculated in accordance with the following formula.

$$α = \frac{\left({\text{X}}_{\text{Ti}} \times {\text{K}}_{\text{Ti}} \div {\text{M}}_{\text{Ti}}\right) + \left({\text{X}}_{\text{Zr}} \times {\text{K}}_{\text{Zr}} \div {\text{M}}_{\text{Zr}}\right) + \left({\text{X}}_{\text{Al}} \times {\text{K}}_{\text{Al}} \div {\text{M}}_{\text{Al}}\right)}{\left({\text{X}}_{\text{Si}} \times {\text{K}}_{\text{Si}} \div {\text{M}}_{\text{Si}}\right) + \left({\text{X}}_{\text{Ti}} \times {\text{K}}_{\text{Ti}} \div {\text{M}}_{\text{Ti}}\right) + \left({\text{X}}_{\text{Zr}} \times {\text{K}}_{\text{Zr}} \div {\text{M}}_{\text{Zr}}\right) + \left({\text{X}}_{\text{Al}} \times {\text{K}}_{\text{Al}} \div {\text{M}}_{\text{Al}}\right)} \times 100 \qquad \text{[Formula 3]}$$

For example, in the case where the bonding layer 105 contains Si atoms and Ti atoms but does not contain Zr atoms and Al atoms, the percentage α (atomic%) of the total number of Ti atoms, Zr atoms, and Al atoms constituting the bonding layer 105 can be calculated in accordance with the following formula.

$$α = \frac{\left({\text{X}}_{\text{Ti}} \times {\text{K}}_{\text{Ti}} \div {\text{M}}_{\text{Ti}}\right)}{\left({\text{X}}_{\text{Si}} \times {\text{K}}_{\text{Si}} \div {\text{M}}_{\text{Si}}\right) + \left({\text{X}}_{\text{Ti}} \times {\text{K}}_{\text{Ti}} \div {\text{M}}_{\text{Ti}}\right)} \times 100 \qquad \text{[Formula 4]}$$

In the present embodiment, K_{Si} = 1.000, K_{Ti} = 1.033, K_{Zr} = 5.696, and K_{Al} = 1.050 are set.

Hereinafter, the near-infrared cut filter 100B in the present embodiment will be further described by using Examples, but the present invention should not be limited to Examples below.

### Example 23

The bonding layer 105 was formed on the glass substrate 101 in Example 1 in the following procedure (4. Formation of Bonding Layer 105). Then, the resin layer 102 was formed on the upper surface of the bonding layer 105 in the same procedure as in Example 1 (2. Formation of Resin Layer 102), thereby fabricating the near-infrared cut filter 100B.

### [4. Formation of Bonding Layer 105]

### 1. Preparation of Coupling Agent-Containing Coating Solution

(1) In a container, 0.3 mL of 0.5 N (mol/L) HCl aqueous solution and 2.2 mL of 2-methoxyethanol were weighed and mixed under a sealed condition.

Tetraethyl orthosilicate (Si(OC₂H₅)₄) was added to the above container, followed by mixing for 30 minutes under a sealed condition to cause a reaction represented by the following reaction formula.

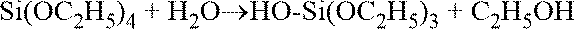

Since the above reaction consumes all the water and generates hydroxy groups, it was expected that even if the alkoxide of Ti, which hydrolyzes at a high speed, was added, the solution became homogeneous without precipitating any hydroxide.

Titanium (IV) n-butoxide (Ti(OC₄H₉)₄) was further added to the above container at a predetermined percentage (for example, 3 to 20 mol%), followed by mixing for 30 minutes under a sealed condition to prepare the coupling agent-containing coating solution.

It is considered that the above process caused a reaction represented by the following formula in the container.

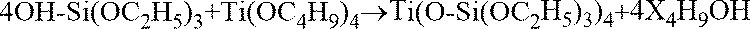

### 2. Formation of Coating Film

In the container containing the above coupling agent-containing coating solution, 1.2 mL of 0.5 N HCl aqueous solution, 4.7 mL of water, and 8.1 mL of 2-methoxyethanol were further weighed, followed by mixing for 30 minutes under a sealed condition to prepare a coating film forming solution.

It is considered that the above process caused reactions represented by the following formulas in the container.

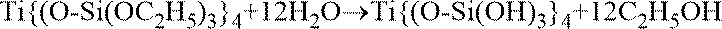

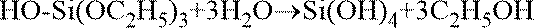

The coating film forming solution thus obtained was applied at 0.03 mL/cm2 onto the glass substrate 101 by using a spin coater.

The glass substrate 101 on which the coating film forming solution was applied was placed on a hot plate heated at 250° C., and heated for 30 minutes to cause dehydration condensation, thereby forming a cured film (the bonding layer 105) on the surface.

Next, the resin layer 102 was formed on the upper surface of the bonding layer 105 in the same procedure as in Example 1 (2. Formation of Resin Layer 102), thereby fabricating the near-infrared cut filter 100B.

When the bonding layer 105 is formed between the glass substrate 101 and the resin layer 102 as described above, the adhesion between the glass substrate 101 and the resin layer 102 can be enhanced and accordingly the reliability can be improved.

The bonding layer 105 in the present embodiment contains one or more kinds selected from Ti atoms, Zr atoms, and Al atoms together with Si atoms. Instead of forming the bonding layer 105, the resin layer 102 may contain the components in the bonding layer 105. Specifically, the resin layer 102 may be structured to contain one or more kinds selected from Ti atoms, Zr atoms, and Al atoms together with Si atoms.

The bonding layer 105 in the present embodiment contains one or more kinds selected from Ti atoms, Zr atoms, and Al atoms together with Si atoms. Instead, a deposition type or coating type of transparent adhesive, for example, can be applied as long as the adhesive can enhance the adhesion between the glass substrate 101 and the resin layer 102.

The resin layer 102 in the present embodiment is formed on one main surface of the glass substrate 101 (the upper surface in FIG. 26) with the bonding layer 105 interposed in between, but the resin layer 102 may be formed on the other main surface (the lower surface in FIG. 26) of the glass substrate 101 with the bonding layer 105 interposed in between as in the first embodiment. Instead, the resin layers 102 may be formed on both surfaces of the glass substrate 101. Moreover, the resin layer 102 does not necessarily have to be a single layer, and may be composed of multiple layers.

The bonding layer 105 in the present embodiment is used for the purpose of bonding the glass substrate 101 and the resin layer 102 together, but may be used as a protective layer (anti-dimming (AD) coat) to protect the glass substrate 101.

### Example 24

FIG. 27 illustrates Example in which the bonding layer 105 in the present embodiment was applied to protective layers 107 (AD). As illustrated in FIG. 27, in Example 24, a protective layer 107, the resin layer 102, and the anti-reflective film 103 are formed in this order on one main surface of the glass substrate 101 and a protective layer 107 is formed on the other main surface of the glass substrate 101.

In Example 24, since the protective layers 107 are formed on both main surfaces of the glass substrate 101, the glass substrate 101 is prevented from deteriorating (such as dimming).

### Example 25

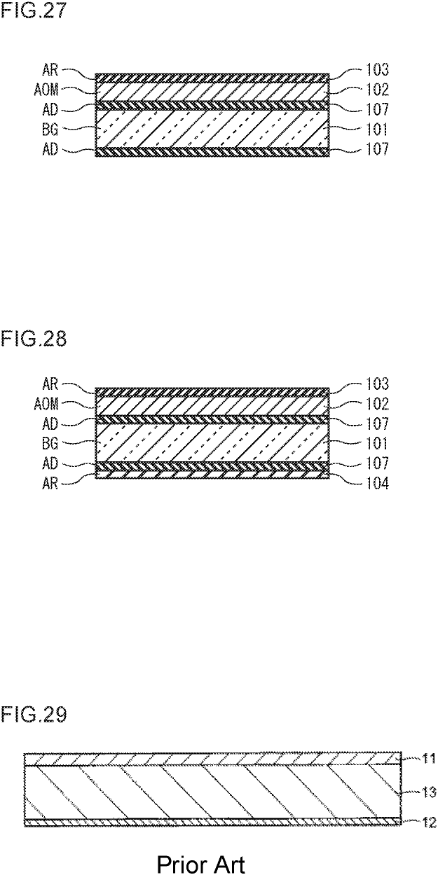

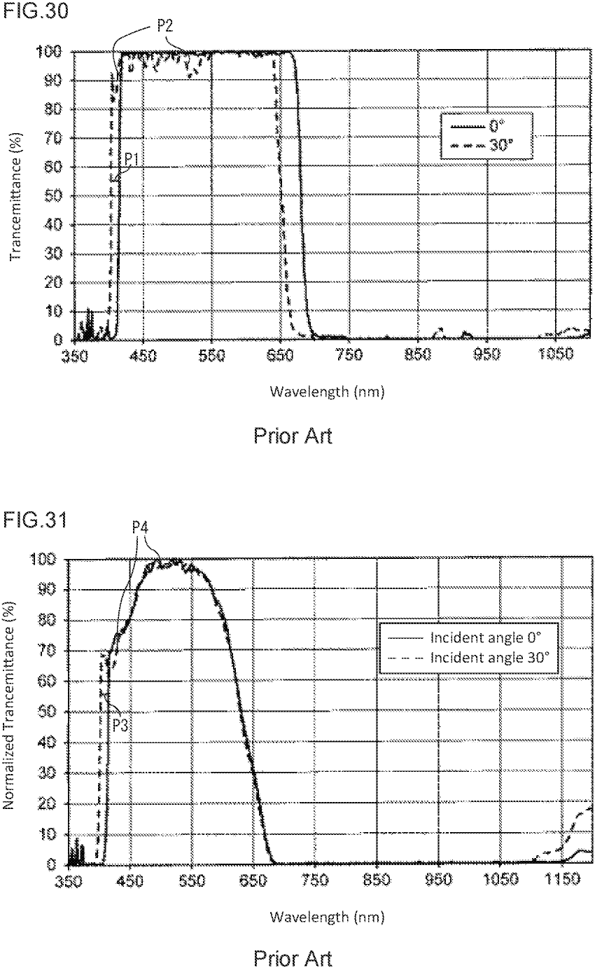

FIG. 28 illustrates a near-infrared cut filter in which the anti-reflective film 104 is further formed on the protective layer 107 on the lower side (on the other main surface) illustrated in FIG. 27.

In Example 25, since the anti-reflective film 104 is further formed on the protective layer 107, it is possible to suppress reflection at the boundaries (i.e., the incident surface and the exit surface) and thereby enhance (improve) the transmittance.

It should be noted that the embodiments disclosed herein should be considered to be exemplary and nonrestrictive in all respects. The scope of the present invention is specified not by the above description but by the scope of claims, and is intended to include all modifications within the meaning and scope equivalent to the scope of claims.

REFERENCE SIGNS LIST

| | |
|---|---|
| 1 | imaging device |
| 11 | absorbing layer |
| 12 | reflective layer |
| 13 | transparent substrate |
| 100 | near-infrared cut filter |
| 100A | near-infrared cut filter |
| 100B | near-infrared cut filter |
| 101 | glass substrate |
| 102 | resin layer |
| 103 | anti-reflective film |
| 104 | anti-reflective film |
| 105 | bonding layer |
| 107 | protective layer |
| 200 | solid-state image sensor |
| 300 | package |

1. A near-infrared cut filter comprising:
a transparent substrate having a thickness of 0.16 to 0.26 mm and an average transmittance in a wavelength range of 800 to 1100 nm of 1% or less; and
a resin layer formed on at least one main surface of the transparent substrate and configured to absorb light of a specific wavelength.

2. The near-infrared cut filter according to claim 1, wherein the transparent substrate has a transmittance curve in which a half-value wavelength on a short wavelength side is 300 to 400 nm and a half-value wavelength on a long wavelength side is 590 to 670 nm.

3. The near-infrared cut filter according to claim 1, wherein the transparent substrate has an average transmittance in a wavelength range of 650 to 720 nm of 40% or less.

4. The near-infrared cut filter according to claim 1, wherein the transparent substrate has an average transmittance in a wavelength range of 720 to 750 nm of 15% or less.

5. The near-infrared cut filter according to claim 1, wherein the transparent substrate has an average transmittance in a wavelength range of 800 to 1200 nm of 5% or less.

6. The near-infrared cut filter according to claim 1, wherein the resin layer contains a transparent resin and a dye evenly dispersed in the transparent resin.

7. The near-infrared cut filter according to claim 6, wherein the dye contains an ultraviolet absorbing dye having a maximum absorption wavelength at 340 to 400 nm.

8. The near-infrared cut filter according to claim 6, wherein the dye contains a near-infrared absorbing dye having a maximum absorption wavelength at 650 to 900 nm.

9. The near-infrared cut filter according to claim 1, wherein the resin layer contains Si atoms as an essential component and contains one or more kinds selected from Ti atoms, Zr atoms, and Al atoms as an optional component.

10. The near-infrared cut filter according to claim 1, further comprising a bonding layer between the transparent substrate and the resin layer, the bonding layer enhancing adhesion between the transparent substrate and the resin layer.

11. The near-infrared cut filter according to claim 10, further comprising the bonding layer on the other main surface of the transparent substrate.

12. The near-infrared cut filter according to claim 10, wherein the bonding layer has a single-layer structure containing one or more kinds selected from Ti atoms, Zr atoms, and Al atoms together with Si atoms.

13. The near-infrared cut filter according to claim 12, wherein, in the bonding layer, a percentage of a total number of Ti atoms, Zr atoms, and Al atoms to a total number of Si atoms, Ti atoms, Zr atoms, and Al atoms is more than 0 atomic% and is equal to or less than 50 atomic%.

14. The near-infrared cut filter according to claim 1, further comprising:
a first functional film on the resin layer; and
a second functional film on the other main surface of the transparent substrate.

15. The near-infrared cut filter according to claim 14, wherein the first functional film and the second functional film are optical thin films each having at least one or more functions of an anti-reflective film, an infrared cut film and an ultraviolet cut film.

16. The near-infrared cut filter according to claim 15, wherein each of the first functional film and the second functional film is composed of a dielectric multilayer film having a thickness of 500 nm or less.

17. The near-infrared cut filter according to claim 16, wherein the dielectric multilayer film is formed by alternately stacking a low refractive index dielectric film and a high refractive index dielectric film.

18] The near-infrared cut filter according to claim 1, wherein the near-infrared cut filter has a transmittance curve in which a half-value wavelength on a short wavelength side is 385 to 430 nm and a half-value wavelength on a long wavelength side is 590 to 660 nm.

19. The near-infrared cut filter according to claim 1, wherein a difference between the half-value wavelength on the long wavelength side in the transmittance curve of the transparent substrate and a half-value wavelength on a long wavelength side in a transmittance curve of the near-infrared cut filter is 20 nm or less.

20. The near-infrared cut filter according to claim 1, wherein the transparent substrate is made of a fluorophosphate-based glass or a phosphate-based glass.

21. An imaging device comprising a solid-state image sensor and the near-infrared cut filter according to claim 1.

22. The imaging device according to claim 21, wherein the near-infrared cut filter is arranged immediately in front of the solid-state image sensor and also serves as a cover glass.
